(19) United States
(12) Patent Application Publication
(10) Pub. No.: US 2025/0259322 A1
(43) Pub. Date: Aug. 14, 2025

(54) METHOD AND DEVICE FOR DETERMINING A TOPOGRAPHY CONTRAST AND/OR A MATERIAL CONTRAST OF A SAMPLE

(71) Applicant: Carl Zeiss SMT GmbH, Oberkochen (DE)

(72) Inventors: Daniel Schwarz, Oberkochen (DE); Daniel Alexander Emmrich, Roßdorf (DE)

(21) Appl. No.: 19/046,800

(22) Filed: Feb. 6, 2025

(30) Foreign Application Priority Data
Feb. 6, 2024 (DE) 10 2024 103 589.7

(51) Int. Cl. G06T 7/55; G06T 7/00

(52) U.S. Cl. CPC G06T 7/55; G06T 7/001; G06T 2207/10061; G06T 2207/20048; G06T 2207/20081; G06T 2207/20084; G06T 2207/30148

(57) ABSTRACT

The present invention relates to a method and a device for determining a topography contrast and/or a material contrast of a sample. The method comprises the following steps: (a) providing at least two image representations of the sample recorded at least partly at different solid angles relative to the sample; and (b) determining the topography contrast and/or the material contrast of the sample at least partly on the basis of the at least two image representations of the sample.

### CROSS-REFERENCE TO RELATED APPLICATION

The present patent application claims the priority of the German patent application DE 10 2024 103 589.7, entitled “Verfahren und Vorrichtung zum Bestimmen eines Topographiekontrasts und/oder eines Materialkontrasts einer Probe” [Method and device for determining a topography contrast and/or a material contrast of a sample], which was filed at the German Patent and Trademark Office on Feb. 8, 2024, the entire content of which is hereby incorporated by reference into this application.

### TECHNICAL FIELD

The present invention relates to a method and a device for determining a topography contrast and/or a material contrast of an image representation of a sample.

### BACKGROUND

As a consequence of the constantly increasing integration density in microelectronics, lithographic masks have to image ever smaller structure elements into a photoresist layer of a wafer. In order to meet these requirements, their exposure wavelength is being shifted to ever shorter wavelengths. At the present time, argon fluoride (ArF) excimer lasers are often used for exposure purposes, these lasers emitting at a wavelength of 193 nm. However, light sources which emit in the extreme ultraviolet (EUV) wavelength range (10 nm to 15 nm) and corresponding EUV masks are also being used. The resolution capability of wafer exposure processes has been increased by simultaneous further development of multiple variants of conventional binary lithographic masks. Examples thereof are phase masks or phase-shifting masks and masks for multiple exposure.

On account of the ever decreasing dimensions of the structure elements, lithographic masks, in particular photolithographic masks, or masks in general cannot always be produced without defects that are printable or visible on a wafer. Owing to the expensive production of photomasks, defective masks are repaired whenever possible. This likewise applies to microscopic samples or components, such as stamps for nanoimprint lithography.

Two important groups of defects in lithographic or photolithographic masks are firstly dark defects. These are places where absorber and/or phase-shifting material is present, but which should be free of this material. These defects are repaired by removing the excess material preferably with the aid of a local etching process.

Secondly, there are so-called clear defects. These are defects on the photomask where absorber and/or phase-shifting material is absent and which, upon optical exposure in a wafer stepper or wafer scanner, therefore have e.g. a greater light transmissivity than an identical defect-free reference position. In mask repair processes, these defects can be corrected by depositing a material having suitable optical properties. Ideally, the optical properties of the material used for the repair should correspond to those of the absorber or phase-shifting material. The layer thickness of the repaired location can then be adapted to the dimensions of the layer of the surrounding absorber or phase-shifting material.

Usually, both types of defects are local defects, the dimensions of which are typically in the submicrometer range. These defects are often repaired by particle beam-induced local chemical processes. In order to repair local defects of a sample, usually at least one process gas is provided at the processing site on the sample at which a focused particle beam induces a local chemical reaction. For local removal of excess material from the sample, the process gas comprises at least one etching gas. In the case of the deposition of missing material, the process gas comprises at least one deposition gas.

In the following text, masks, stamps for nanoimprint lithography, wafers and various types of components to be repaired, such as MEMS (Micro-Electro-Mechanical System), NEMS (Nano-Electro-Mechanical System) or PICs (Photonic Integrated Circuits) are grouped together under the term sample.

In contrast to mechanical processes, such as sputter processes, chemical processes are often slow-moving processes. This means that the local chemical repair processes for a sample may progress on a time scale in the single- or double-digit minutes range. In order to attain reproducible results during a sample repair, the local chemical process must be stopped at the correct point in time, preferably automatically. A suitable point in time when depositing a phase-shifting layer onto a photomask, for example, is the point in time at which the repaired location has the same absorbing and phase-shifting properties as a comparable non-defective region of the mask. During a local etching process, the correct point in time is reached when a layer to be removed has been etched, but if possible before the etching process begins to etch the underlying layer of the sample. An image representation of the sample that yields specific information about the local material composition of the sample may thus be used for ascertaining the point in time for stopping a repair process performed by use of a local chemical reaction.

A particle beam (e.g. an electron beam) (e.g. the same one that is used for initiating the local chemical repair process) is often used for imaging the sample to be repaired. This particle beam causes for example a local emission of secondary electrons (SE) and electrons backscattered from the sample (BSE, backscattered electrons). Depending on the type of detector used for detecting the SE and BSE, the arrangement of said detector in relation to the solid angle distributions of the SE and BSE, and possibly an energy filter present, the detector records SE and BSE portions having different magnitudes.

The SE emanating from a sample are typically more frequent than the BSE by a multiple. What is more important, however, is that the SE are principally responsible for the topography contrast of a sample image representation, whereas the BSE, in particular the portion that leaves the sample in a small solid angle range antiparallel to the primary particle beam, predominantly carries information about the local material composition of the sample.

Therefore, the BSE emitted substantially antiparallel to the beam direction of the primary particle beam are particularly suitable for determining a stop signal of a local chemical repair process. However, a detector arranged for example around the primary particle beam, for instance an electron beam, nevertheless always simultaneously detects SE and BSE. This detector arrangement generally does not permit a complete separation of the SE and BSE. Rather, such a ring-shaped detector typically receives a BSE signal with an SE signal background superimposed thereon. Introducing an electrical opposing field makes it possible to at least partly separate SE and BSE in a sample image representation. Nevertheless, the image representation of a sample imaged using a detector with an integrated energy filter is suitable only to a limited extent as a stop signal for a local particle beam-induced repair process if it indeed still has portions of topography contrast and material contrast. Moreover, the incorporation of a detector with an integrated energy filter is often associated with quite major technical challenges.

The present invention therefore addresses the problem of specifying a method and a device for determining a topography contrast and/or a material contrast of an image representation of a sample.

### SUMMARY

In accordance with one exemplary embodiment, this problem is solved by a method according to Claim 1. In one embodiment, the method for determining a topography contrast and/or a material contrast of a sample comprises: (a) providing at least two image representations of the sample recorded at least partly at different solid angles relative to the sample; and (b) determining the topography contrast and/or the material contrast of the sample at least partly on the basis of the at least two image representations of the sample.

The inventors have recognized that the secondary particles emitted by a sample (backscattered particles or particles ejected from the sample) have an inhomogeneous solid angle distribution. As a result, two sample image representations recorded at different solid angles and based on the detection of secondary particles, in particular secondary electrons (SE) and backscattered electrons (BSE), a priori contain different information about their topography contrast and material contrast. Moreover, the energy distribution of the secondary particles changes as a function of the solid angle into which these are emitted. Linking the information contained in the at least two image representations makes it possible to ascertain the topography contrast and material contrast portions contained in the individual image representations. By contrast, a single detector that records secondary particles (for example SE and BSE) from the same solid angle ranges as two or more detectors averages over both the solid angle distribution and the energy distribution of the secondary particles used for generating the image representations. As a result, the information present in these distributions of the secondary particles is lost.

One advantage of the method according to one or more embodiments is that none of the detectors used for recording the image representations requires an energy filter for the secondary particles. This firstly reduces the installation space needed for the detector(s). Secondly, an absent energy filter, for instance in the form of a screening grid, cannot disturb a primary charged particle beam, for instance an electron beam. By way of example, if a ring-shaped detector arranged around the primary charged particle beam comprises a screening grid as an energy filter, the voltage of the screening grid may influence the primary particle beam on the sample, for instance the landing energy of the primary particles, i.e. the particles of the primary particle beam, on the sample.

Furthermore, at edges of a sample, for instance the edges of absorbing pattern elements of photomasks, in an energy-filtered image representation or in an energy-filtered image, topography effects arise as a result of screening effects. Consequently, a pure material contrast image cannot be measured in the region of edges of a sample. By dispensing with an energy filter for secondary particles, a method according to one or more embodiments circumvents this limitation.

During the simultaneous recording of the at least two image representations by use of two detectors, it is advantageous if solid angle ranges of the two detectors overlap as little as possible, at best not at all, in order to minimize the redundancy of the information present in the two image representations. This holds true in the same way if the two image representations are recorded successively by a single detector positioned differently or an individual detector is stopped down successively at different locations.

Providing at least two image representations recorded at different solid angles relative to the sample can comprise at least one element of the following group: loading at least two image representations recorded at different solid angles from a memory, transmitting at least two image representations recorded at different solid angles via a data connection, or recording at least two image representations of a sample at different solid angles.

Image representations or images of a sample can be recorded by scanning a focused primary electron beam, which excites the sample, over the sample or a partial region of the sample and simultaneously detecting secondary electrons (SE) and backscattered electrons (BSE) emanating from the sample.

The focused primary particle beam can comprise a charged particle beam. The charged particle beam can comprise an electron beam and/or an ion beam. A primary particle beam in the form of an electron beam is advantageous.

The secondary particles can be detected by one or more detectors. Detectors used for detecting secondary particle may average or integrate the signals generated by SEs or BSEs across their sensing area. Typically, they do not have local resolution within their sensing area. The detectors may have an array of sensing elements. But the signals of the various sensing elements may be added. The at least one detector can use different detection principles, such as a scintillation counter, e.g. in the form of a scintillator-photomultiplier detector, a semiconductor detector, e.g. a diode structure having one or more segments, or an yttrium aluminium garnet (YAG) detector.

The at least one detector can have different geometries. A detector arranged in the vicinity of the sample, for example an Everhart-Thornley detector, covers a solid angle range that is asymmetric with respect to both the polar angle (the angle relative to the beam axis of the primary particle beam) and the azimuth angle (relative to a straight line in the sample plane). So-called in-lens detectors, for example a Robinson detector, are arranged rotationally symmetrically around the beam axis of the primary particle beam and have an opening for the passage of the primary particle beam. On account of their geometry and arrangement, in-lens detectors thus have no polar angle dependence. When in-lens detectors are arranged in the vicinity of the sample, they record secondary particles of the sample from a large solid angle range. This advantageously improves the signal-to-noise ratio of the detector signal. On the other hand, an in-lens detector averages over large ranges of the energy and solid angle distributions of the secondary particles.

The number of secondary particles that leave the sample per particle of the primary beam, or electron beam, i.e. the yield, depends on the kinetic energy or the landing energy of the primary particles, or electrons. It is often the case that the yield of the secondary particles for very small landing energies is <1, is in a medium energy range >1 and the yield drops into the range <1 again for large landing energies.

The SE portion of the secondary particles denotes electrons emanating from the sample which have a kinetic energy of up to approximately 50 eV; for the most part the SE have kinetic energies of the order of a few eV (electronvolts). If the primary particle beam comprises an electron beam, the electrons backscattered from a sample (BSE electrons) are higher in energy than the SE and typically have kinetic energies of the order of a few keV (kiloelectronvolts). The intensity of a BSE signal is primarily dependent on the atomic number or on the average atomic number if the sample has a material composition in the form of a compound. The intensity of a BSE signal rises with the (average) atomic number. This means that heavy elements lead to a strong backscatter and regions of the sample with heavy elements appear bright as a result of the strong BSE signal. In the present application, the dependence of the strength of a BSE signal on the local material composition can therefore be used for detecting a change in the local material composition of a sample in the z-direction, i.e. perpendicularly to the sample surface.

Determining the topography contrast and/or the material contrast can comprise applying a decoupling model to the at least two image representations. In particular, the determining can comprise applying a parametrized or trained decoupling model to the at least two image representations. A decoupling model comprises a mathematical model which is applied to at least two image representations recorded at different solid angles in order to determine their topography contrast and/or material contrast.

The presence of a signal indicating the local material composition of the mask is important for monitoring purposes, for example vis-à-vis a mask repair process. This signal should be as independent as possible of the local topography of the mask, generally the sample, and at the same time should respond as sensitively as possible to a local change in the material composition of the mask. A local topography takes account of the topography of the mask in the direct vicinity thereof. By way of example, determining a material contrast at the base of an edge is made more difficult by shading effects of the edge.

For a sample, for example in the form of a binary photomask, it is merely necessary to distinguish between the material of the absorbing pattern elements and the material of the mask substrate. For this purpose, at least two, preferably multiple, detector signals are recorded from a point of the sample or mask. The at least two signals of a point, recorded at different solid angles, are processed to form a function in order to generate a material signal. In the simplest form, it is possible to determine a linear combination of the different detector signals from a point of the mask. However, it is also possible to ascertain any other functions of the detector signals. The coefficients of the function can be calibrated for example such that the function assumes the value 0 for the material composition of the pattern elements and the value 1 for the material composition of the mask substrate, or vice versa. This makes it possible to ascertain an image representation of the sample which has substantially exclusively information about the local material composition thereof (referred to as: compositional contrast).

This image representation can be used for automatically stopping a particle beam-induced local chemical repair process for a sample. Sample defects can be repaired reproducibly with the aid of a method according to one or more embodiments. At the same time, sample damage owing to undesired deposition of material onto the sample or unwanted removal of material from the sample during a repair process can be reliably avoided.

The at least two image representations can capture solid angle ranges of the sample whose angles are small relative to the primary particle beam (the image representations can originate, e.g., from detectors which can be arranged around the primary particle or electron beam, so-called in-lens detectors). By way of example, if the detected secondary particles comprise secondary electrons (SE) and backscattered electrons (BSE), this detector arrangement captures a large portion of high-energy BSE which predominantly yield information about the local material composition of the sample.

It goes without saying that the method according to one or more embodiments can be applied to configurations comprising three or more detectors which record three or more image representations at partly different solid angles. By virtue of the use of two or more detectors which receive secondary particles, or SE and BSE, from different solid angle ranges, the distribution of the secondary particles can be resolved and the inhomogeneity thereof can be ascertained, and can be used for determining the topography contrast and/or the material contrast. By contrast, a single detector that receives secondary particles from the different solid angle ranges of the two or more detectors integrates or averages over the inhomogeneous solid angle distribution of the secondary particles. The precision of the determination of the local material composition of the sample therefore increases with the number of image representations which are recorded at different solid angles and which are available to a method according to one or more embodiments as input data.

If a planar sample surface is imaged and the focused particle or electron beam impinges on the sample surface with normal incidence, different solid angles comprise different angles with respect to the primary focused particle or electron beam or different polar angles.

In the case of a configuration with two in-lens detectors, wherein the first detector is positioned nearer to the sample than the second detector, a first image representation out of the at least two image representations, which is recorded by the first detector, can comprise for SE a solid angle in the range of 0.6 sr to 1.0 sr, preferably 0.26 sr to 1.2 sr, and most preferably 0.15 sr to 0.4 sr, and for BSE a solid angle in the range of 0.3 sr to 1.3 sr, preferably 0.5 sr to 1.6 sr, and most preferably 0.8 sr to 2.0 sr. A second image representation out of the at least two image representations, which is recorded by the second detector, can comprise for SE a solid angle in the range of 0.2 sr to 0.6 sr, preferably 0.15 to 1.3 sr, and most preferably 0.05 sr to 0.15 sr, and for BSE a solid angle in the range of 0.15 sr to 0.6 sr, preferably 0.1 sr to 0.26 sr, and most preferably 0.05 sr to 0.15 sr. The abbreviation “sr” stands for steradian.

In the example of an in-lens arrangement of one or more detectors in a column of a scanning electron microscope (SEM), the solid angle range from which SE and BSE are incident on the detector(s) is dependent on their kinetic energy. The secondary particles are focused by the objective lens of the SEM in the back focal plane thereof. The lower the kinetic energy of the secondary particles, i.e. SE and BSE, the nearer to the sample this focal point is. In a best possible arrangement, the first detector is positioned in the focal plane of the BSE, such that a maximum proportion of the BSE can reach the second detector and the first detector simultaneously keeps a largest possible portion of the SE away from the second detector. The primary task of the objective lens is the focusing of the primary charged particle beam onto the sample, i.e. the front and back focal planes of the objective lens are dependent on the chosen settings of the primary electron beam or on the distance between the sample and the objective lens.

The at least two image representations can be recorded simultaneously by two detectors that view the sample from two partly different directions. In this case, one of the detectors can partly conceal or shade the solid angle range seen by the second detector.

However, it is also possible for the two image representations to be recorded successively by one detector. In this case, the detector should be brought from the first imaging position to the second imaging position between the first and second imagings or image recordings. Shading effects of the simultaneous imaging by use of two detectors can likewise be taken into account during a progressive image recording by use of one detector when determining the topography contrast and material contrast portions of the at least two image representations. Furthermore, it is possible to cover a first part of an individual detector during a first imaging and a second part of the individual detector during a second imaging. In this case, it is advantageous if the individual detector has the largest possible detection area.

A detector collects secondary particles which a primary particle or electron beam detaches from a point of the sample and which reach the input opening of the detector. By way of two-dimensionally scanning the primary electron beam over the sample, a two-dimensional intensity distribution of the secondary particles, i.e. an image representation of the sample, is simultaneously generated on a monitor.

Hereinafter a sample is imaged by way of scanning using a primary focused particle beam. Scanning the sample using the primary particle beam, preferably an electron beam, causes secondary particles (electrons) to leave the sample at the location of incidence of the primary particles (electrons), said secondary particles being recorded by one detector or a plurality of detectors, the detector(s) generating a two-dimensional intensity pattern of the sample as a result. The number of secondary particles detached from the sample per incident primary particle depends not only on the material of the sample but also on the surface topography thereof. From local raised parts of the sample, such as along edges of elevations, for example along the edges of pattern elements, the local angular range of the sample surface into which secondary particles can be emitted is greater than 180° or greater than π. Therefore, local elevations and/or edges generate more secondary particles than a planar sample surface. As a result, these appear brighter in comparison with a planar sample surface. In the region of local depressions, by contrast, the angular range into which the sample can emit secondary particles is less than 180° and these therefore appear darker in an image representation of the sample, once again in comparison with planar surface regions of the sample.

In the case of a planar sample surface and a predefined landing energy of the primary particles, the number and the angular distribution of the secondary particles are substantially dependent on the material or the material composition of the sample. If the secondary particles are electrons, scaled for landing energies >600 eV the number of backscattered electrons (BSE) generated is approximately proportional to the mass number of the sample material. This means that for a predefined particle current the local intensity of the sample image representation is all the greater, the greater the mass number of the local sample material.

The contributions stemming from the local material composition and the local surface contour or surface topography are typically superimposed in an intensity distribution with corresponding contributions. An important aspect of the present application is to separate these contributions.

As will be explained below, a predefined sample image representation generally has both a topography contrast portion specific to it and a material contrast portion. In a coordinate system spanned by a pure topography contrast portion (T-axis) and a pure material contrast portion (M-axis), sample image representations therefore generally do not lie on one of these axes. A parametrized empirical model can firstly perform a rotation of a sample image representation, such that the latter becomes located on the M- or T-axis of the coordinate system (and thus has exclusively the material contrast portion thereof or the topography contrast portion thereof). The respective angle of rotation indicates the magnitude of the topography contrast portion or material contrast portion of the analyzed sample image representation.

The parametrized empirical model can more generally perform a change in position of an image representation of the sample in a plane spanned by its topography contrast portion and its material contrast portion.

For example, the parametrized empirical model can separate the sample image representation to be examined into the material contrast and topography contrast portions thereof, i.e. represent it as a linear combination (e.g. of two unit vectors of the M-axis and the T-axis). This is equivalent to the projection of the sample image representation to be analyzed or to be determined onto the T-axis and the M-axis of the M/T-coordinate system. It is e.g. also possible for the material contrast portions of both image representations then to be added to form an overall image.

In both cases, the material contrast of the sample can be ascertained. A change in the sample image representation having exclusively material contrast unambiguously and reliably reveals a change in the local material composition of the sample. Such a change occurs for example when an etching process reaches a layer boundary. The change in the material contrast portion that is separated from a sample image representation can be used for controlling a particle beam-induced local chemical repair process.

The material contrast of a sample can be ascertained by solving an optimization problem. In this case, it is advantageous to use all available data of a sample for solving the optimization problem. By way of example, samples in the form of lithographic masks greatly restrict the material composition of the components of the mask—these are the mask substrate and the absorbing pattern elements in the simplest case of binary masks. In this regard, the pure M and T portions of a mask image representation can be determined from the design data. Moreover, the design data can be used for creating an empirical model for a specific type of mask. The detector configuration used for recording the at least two image representations, i.e. the configuration of the distances between the individual detectors and the sample and between one another, can be taken into account when creating the empirical model. Furthermore, the empirical model can comprise one or more parameters defining the operating point of the SEM. The operating point comprises at least the parameters: a kinetic energy of the particles of the primary charged particle beam, a distance between the sample and the objective lens, and an aperture angle of the primary particle beam.

The decoupling model can comprise at least one element from the following group: an empirical model or a transformation model.

A decoupling model can pursue various approaches for analyzing an image representation with regard to the topography contrast and material contrast portions contained. An empirical model can establish an analytical connection between two or more image representations and their different topography contrast and material contrast constituents. By contrast, a transformation model can dispense with setting up a functional relationship between the solid angle distributions contained in two or more image representations for the detected secondary particles and the local topography and material composition of the sample. Rather, this connection can be implicitly established or learned by way of the training of the transformation model.

The decoupling model can be designed to link the at least two image representations with one another. Electron-optical simulations can be carried out in order to determine the solid angle distribution(s) or the acceptance function(s) of the one or more detectors. In combination with simulated angular distributions of the SE and the BSE, a decoupling model can be set up for the M and T portions of the at least two image representations.

Linking the at least two image representations can comprise: linearly modifying the at least two image representations and combining the at least two modified image representations. Combining the at least two modified image representations can comprise at least one element from the following group: adding the at least two modified image representations, subtracting the at least two modified image representations, multiplying the at least two modified image representations, or dividing the at least two modified image representations. Furthermore, linking the at least two image representations can comprise: determining a material contrast portion of at least one of the at least two image representations from the at least two linked image representations.

As explained above, a sample image representation generated by scanning the sample with the aid of a primary particle beam includes intensity portions stemming from both the surface topography and the material composition of the sample. These portions cannot be straightforwardly separated when a single sample image representation is considered. Besides the landing energy of the primary particles, however, these portions also vary as a function of the solid angle at which the sample or a part of the sample or a sample region is viewed.

An empirical model can link at least two image representations which generate secondary particles which leave the sample at least partly at different solid angles. The solid angle ranges from which the secondary particles of the two image representations originate are known from the arrangement of the detector(s). This makes it possible to use the at least two image representations of the sample to ascertain the topography contrast portions and material contrast portions thereof.

A method according to one or more embodiments can furthermore comprise the step of: adapting the empirical model to the sample. The complexity of an empirical model can be adapted to the complexity of the sample to be imaged. The complexity of a sample depends on the contour or structure(s) thereof and the material or material composition of the sample. By way of example, for samples whose structures have only small differences in the atomic masses, the decoupling is more difficult compared with samples whose structures have large atomic mass differences. Samples whose structures have small atomic mass differences require complex decoupling models.

Adapting the empirical model can comprise adapting the parameters of the empirical model to the number of different material compositions of the sample. A sample in the form of a binary photomask is characterized by two components having different material compositions. By contrast, a phase-shifting mask has at least three components having different material compositions. An empirical model having two parameters is sufficient for ascertaining a material contrast image representation and/or a topography contrast image representation of a binary mask. By contrast, an empirical model for a phase-shifting mask requires at least three parameters.

A method according to one or more embodiments can furthermore comprise: determining the parameters of the empirical model.

Determining the parameters of the empirical model can comprise at least one element from the following group: recording at least two image representations of at least one calibrated test structure at at least two different solid angles, simulating at least two image representations of the at least one calibrated test structure at different solid angles, or recording at least two image representations of the at least one calibrated test structure at different solid angles, wherein at least one detector has an activated screening grid.

Recording the at least two image representations can take place at at least one first and at least one second position of the calibrated test structure, wherein the at least one first and the at least one second position have different material compositions. This means that, in the case of a calibrated test structure for a binary mask, at least two image representations are recorded at different solid angles of the mask substrate and at least two image representations are recorded at different solid angles of an absorbing pattern element. For a phase-shifting mask, at least two image representations are recorded at different solid angles of the mask substrate, at least two image representations of the phase-shifting material are recorded and at least two image representations of the absorbing material of a pattern element are recorded. The material contrast portions and the topography contrast portions of a calibrated test structure are known on account of the calibration performed.

Simulating the at least two image representations can comprise performing Monte Carlo simulations of the interaction of the primary particle beam with the sample and an electron-optical simulation of the path of the secondary particles from the sample to the at least two detectors.

Determining the parameters of the empirical model can comprise: varying the parameters of the empirical model for minimizing a difference between a measured image representation of the sample and a measured or simulated image representation of the calibrated test structure.

For the purpose of determining a local material signal or a punctiform image representation having exclusively signal portions stemming from the material contrast, a local or punctiform sample image representation can be recorded by one or more detectors at a point of a sample (pixel-by-pixel determining) and can be processed in a function in order to determine a material signal of the point of the sample surface. In the simplest form, a linear combination of the two or more detector signals can be taken for this purpose. It goes without saying that the detector signals are combinable in other functions. The coefficients of the function can be determined by comparing with a calibrated test structure whose material signal (i.e. whose material contrast portion of an image representation) is known.

For a sample composed of two components, for instance a binary photomask, the coefficients of the function can be calibrated such that they assume the value 1 for the first component, for instance the mask substrate, and the value 0 for the second component, for instance the absorbing pattern elements.

The last-described embodiment for determining the parameters of an empirical model does not require the primary particle beam to be scanned over the sample, since exclusively signals of the sample which emanate from a point of the sample surface are processed. The greater the number of signals of different detectors which can be processed, the higher the accuracy with which the local material signal of the sample can be ascertained. This means an advantage over an individual energy-filtered signal which at present is often used for determining a material contrast portion. The use of two or more detectors enables more secondary particles locally emanating from the sample to be detected and thereby made usable. As a result, a better signal-to-noise ratio can be achieved and/or the data recording can take place more rapidly.

Since the measured topography data of the sample are not perfectly local and moreover detector-dependent, they cannot be completely compensated for when locally determining the parameters of the abovementioned empirical model. However, the compensation portion increases with the number of detectors used. Furthermore, the parameters of the empirical model have to be optimized for each operating point (landing energy of the primary particles or electrons, distance between the mask and the objective lens, settings of the objective lens, etc.) and for each type of sample or type of mask.

Determining an image representation having only material contrast contributions on the basis of an empirical model can comprises scanning a primary particle beam over a sample and recording at least two detector signals at the scanning points of the primary particle or electron beam.

The pixel-by-pixel determining of the parameters of the empirical model as discussed above disregards non-local effects on account of the sample topography. By means of the primary particle beam being scanned over a part of the sample, the non-local signal portions of the at least two detector signals can be taken into account when determining the parameters of the empirical model.

Instead of the recording of a signal at just one point, a plurality of image signals are recorded for each of the at least two detectors by use of a scan of the primary beam over a part of the sample. Performing a convolution with one or more convolution kernels enables new signals to be generated from the images of the individual detectors. The parameters of the empirical model can be determined by way of an adaptation of the convolved measurement data to the measurement of a calibrated test structure.

At least one image filter from the following group can be used as a convolution kernel: a Sobel filter, a Prewitt filter, a Laplacian filter, a Marr-Hildreth filter, a Gaussian filter, or a Sharpen filter. The size of the convolution kernel can be adapted to the size of the scanning region. The scanning region of the primary particle beam should be chosen to be larger than the image region of the convolution kernel. In order to uphold the accuracy of the convolution operation, it is additionally advantageous to choose the size of the scanning region such that the procedure at the edge region (for example extending, wrap convolution or cropping) remains below a predefined error threshold. The scanning region can comprise in one dimension a dimensioning in the range of 2 nm to 50 nm, preferably 5 nm to 20 nm.

Determining the parameters of the empirical model from a scanning region instead of pixel-by-pixel determining makes it possible to significantly reduce the remaining topography effects in a material contrast image representation of a sample or sample segment. Against the advantage of a significant improvement in quality, there is the opposing disadvantage of a significantly higher complexity. Scanning over a sample region takes longer than recording images or image representations of an individual sample point. The size of a convolution kernel can be ascertained by performing Monte Carlo simulations. The optimization process for determining the parameters of the empirical model should be performed for each type of sample and each operating point.

After the parameters of an empirical model have been defined, this empirical model can compute at least two image representations of a sample, said image representations having different topography contrast and material contrast portions, with one another in such a way that the topography contrast and material contrast portions of the at least two submitted sample image representations can be extracted from the latter.

The transformation model can comprise at least one transformation model having at least two transformation blocks, each comprising at least one generically learnable function, preferably a machine learning model, and/or a generative model.

A trained transformation model can transform an image representation from at least two image representations measured at at least partly different solid angles into an image representation having a predefined portion of topography contrast and/or material contrast. In particular, a transformation model can be trained to transform a measured image representation such that the transformed image representation exclusively indicates the material contrast portion of the submitted image representation to be analyzed. Alternatively and/or additionally, it is also possible to train a transformation model such that it outputs the topography contrast portion and/or the material contrast portion of one of the two measured image representations as a numerical value. A change in the material contrast portion that exceeds a predefined threshold value can be used for detecting the change in a local material composition.

However, a transformation model can also be trained such that it transforms both or all of the at least two measured image representations into image representations which each have a predefined ratio of topography contrast and material contrast. Furthermore, it is possible to train a transformation model such that the first transformed image representation exclusively shows topography contrast and the second transformed image representation exclusively represents material contrast.

A transformation model need not comprise a sequence of encoder, feature projection and decoder. Instead, a generic, learnable function can be provided in each of the N layers (e.g. of a neural network), which function converts inputs into outputs without having the demand to generate a suitable and thus transferable representation (features) of the inputs in one of the intermediate steps.

A generically learnable function of a transformation block of a transformation model obtains the output data of the preceding transformation block as input data. Generally, an N-th transformation block obtains the output data of the (N−1)-th transformation block (O_{N-1}). The output data of the (N−1)-th transformation block are the input data of N-th transformation block (I_{N}): O_{N-1}=I_{N}. The output data of the (N−1)-th transformation block O_{N-1} can comprise the original input data I₁ of the first transformation block in unchanged form. Furthermore, the output data of the (N−1)-th transformation block can comprise the input data of all preceding transformation blocks (I₁, . . . , I_{N-1}) in unchanged form. Furthermore, the input data of the N-th transformation block I_{N} can comprise the input data transformed by the preceding transformation blocks: T_{N-1} (O_{N-2}), P_{N-1})=T_{N-1}(I_{N-1}, P_{N-1}). In this case, T_{N-1} denotes the transformation performed on the input data I_{N-1} in the (N−1)-th transformation block. P_{N} denotes the model parameters of the transformation model in the N-th transformation block.

If, in the N-th transformation block, the transformation T_{N} describes a convolution operator, only the transformed data of the preceding layer T_{N-1}(I_{N-1}, P_{N-1}) are taken into account as input variables or input data I_{N} in this transformation block, and the input data of the earlier transformation blocks I₁, . . . , I_{N-1} are ignored. The model parameters P_{N} of this transformation block correspond to convolutional weights and the N-th transformation block performs the function of a convolutional layer or a convolution block.

A generically learnable function of a transformation block can comprise at least one element from the following group: a convolution block, a deconvolution block, a pooling block, a depooling block, a DenseBlock, a ResBlock, an InceptionBlock, an encoder or a decoder.

A transformation model can be trained to transform at least one image representation of a tuple of measured image representations into a transformed image representation which appears like an image representation having a predefined ratio of topography contrast and material contrast. However, a transformation model can also be trained to convert at least one simulated image representation of a tuple of simulated image representations into a transformed image representation having a predefined topography contrast ratio and/or material contrast ratio.

A machine learning model can comprise an encoder-decoder structure. In encoder-decoder architectures, on the encoder side, input data are mapped (encoded) onto information-carrying features, or features, by a series of learnable functions. From these features, on the decoder side, the target data, in the present case at least one transformed image representation with a predefined topography and/or material contrast portion, are then extracted (decoded) by use of likewise learnable functions. The individual functions both on the encoder side and on the decoder side are usually referred to as layers. In an encoder-decoder architecture, inputs available to a layer are typically the outputs of the preceding layer. However, it is also possible for corresponding layers of the encoder and decoder sides to be connected to one another.

A machine learning model can comprise at least one element from the following group: parametric mapping, a neural network (NN), an artificial neural network (ANN), a deep neural network (DNN), a time-delayed neural network, a convolutional neural network (CNN), a recurrent neural network (RNN), or a long short-term memory (LSTM) network.

A particle beam-induced repair process for a sample can be regarded as a temporal sequence of local image representations of the sample and can thus be interpreted as a video recording. This perspective and the selection of a corresponding network architecture make it possible to significantly increase the accuracy of the transformation to be carried out.

The machine learning model (ML model) can comprise a sub-symbolic system. The knowledge, i.e. the training data and the induced rules, is explicitly represented in the case of a symbolic system. In the case of a sub-symbolic system, a calculable behaviour is taught to the model without, however, having a detailed view into the learnt solution paths.

Furthermore, a machine learning model (ML model) can comprise at least one element from the following group: a kernel density estimator, a statistical model, a decision tree, a linear model, a time-variant model, a nearest neighbour classification, and a k-nearest neighbour algorithm, and their non-linear extensions with non-linear feature transformations.

A kernel density estimator (referred to as: KDE) enables a continuous estimation of an unknown probability distribution on the basis of random samples. Kernel density estimators can comprise for example a Gaussian kernel, a Cauchy kernel, a Picard kernel or an Epanechnikov kernel, wherein the kernel parameters contained in the ML model, such as the bandwidth, for instance, can be allocated or estimated individually or jointly for all input parameters.

The statistical model can comprise at least one mixture distribution. A mixture distribution can comprise an element from the following group: a Gaussian mixture distribution (GMM, Gaussian mixture model), a multivariate normal distribution and a categorical mixture distribution. The suitable number of mixture distributions depends on the data present and can be optimized with the aid of a validation data set.

The decision tree (DT) can comprise at least one element from the following group: a conventional decision tree (DT), a randomized decision tree (RDT) or a decision forest (DF) and the latter's randomized variant (RDF). In RDTs and RDFs, the extent or “level” of the randomization can vary. For each node all or only a random selection of possible decisions can be present in the training. For each leaf of a decision tree all or only a subset of the training examples present up until then can be used.

The linear model can comprise at least one element from the following group: a latent Dirichlet allocation (LDA), a support vector machine (SVM), a logistic regression, a least square method (least square estimation), a Lasso regression, a ridge regression, or a perceptron. An advantageous application of a linear model requires a normalization of the input data and the training data.

The ML model can comprise a non-linear extension of an SVM in the form of a kernel support vector machine. Furthermore, the ML model can comprise a non-linear extension of the Gaussian mixture distribution in the form of a Gaussian process regression.

The time-variant model can comprise at least one element from the following group: a recurrent neural network or a hidden Markov model. A time-variant model can be simulated by a time-invariant model by means of the parameters of an earlier measurement being made available to the time-invariant model as input data.

Furthermore, the ML model can comprise two or more different types of machine learning model from the group specified above. A machine learning model which uses an ensemble or a group of a plurality of different types of model or a plurality of learning algorithms can generally achieve better results than an ML model which is based on a single type of model or learning algorithm. The calculation of the results of the number of different types of model typically takes longer than the evaluation of a single type of ML model. In return, however, a result corresponding to an ML model having one type of ML model or one learning algorithm can already be achieved with a smaller computation depth.

The predictions of the different constituents of the combination can contribute to the prediction of the machine learning model in an equally weighted manner. The predictions of the different types of ML model can contribute to the prediction of the machine learning model in a weighted manner.

A machine learning model which comprises a group of different types of ML model can be built up incrementally in the training phase by each type of model that is newly added to the group being provided with, in particular, the training data that the previous types of model in the group could not predict or could predict only poorly.

The two or more different ML model types of a machine learning model can be selected with the aid of automated machine learning (or AutoML).

The transformation model can comprise a machine learning model, in particular a deep learning model. The machine learning model can use an artificial neural network. The deep learning model can use a deep neural network. A deep neural network comprises a plurality or a multiplicity of intermediate layers (referred to as: hidden layers). A deep learning architecture can also perform a feature extraction of the submitted data besides a classification of the submitted data.

The deep neural network (DNN) can comprise a U-Net architecture or a ResNet architecture.

A U-Net architecture has a symmetry between the encoder and decoder branches, which results in a U-shaped structure of the architecture. Besides the relaying of data between the different layers of the encoder and the decoder, the U-Net architecture can have additional connections between corresponding layers of the encoder and decoder via which output data from a layer of the encoder are directly transferred as additional input data to the corresponding layer of the decoder.

A residual network (ResNet) architecture is an encoder-decoder structure, too, in which data are likewise not just relayed between adjacent layers of the encoder and decoder branches. A ResNet has additional connections via which output data are transferred across a plurality of layers as input data. Output data may thus be transferred to layers that are not next neighbors and/or via a plurality of layers. These additional data transfers typically take place on both the encoder side and the decoder side of the architecture.

The machine learning model can comprise at least one additional parameter which is provided to the machine learning model (ML model) at the input thereof.

As an alternative to the procedure just described, one or more additional parameters are transferred to an ML model besides the measured image representation tuples. The one or more additional parameters are available to the transformation model or the ML model as input both during the training phase and for determining the topography contrast portion and/or the material contrast portion of a measured image representation tuple. This makes it possible to use a kind of generalized model for different types of mask for different parameter settings of the repair device, for prediction purposes. Only a generalized transformation model or ML model need be trained and this can subsequently be used for different types of mask and different settings of the system parameters of the repair device.

The at least one additional parameter can comprise a system parameter of a repair device.

The at least one additional parameter can comprise at least one parameter of the lithographic mask and/or at least one system parameter of the repair device or the imaging system thereof. The at least one parameter of the mask can comprise a mask type, dimensions and material compositions of the mask substrate and/or of the pattern elements, and/or the at least one system parameter can comprise a landing energy of the primary particle beam, an angle of incidence of the primary particle beam on the sample, the exposure setting of the objective lens, an aperture angle of the primary particle beam, a scanning speed of the primary particle beam, an integration time of the primary particle beam (dwell time), a scanning strategy (e.g. line by line, interlace or diagonal scan), an asymmetric arrangement of at least one detector in relation to the beam axis of the primary particle beam, a potential setting of an energy filter, and/or a potential setting of a screening grid at the particle-optical column output.

The ML model can comprise at least one hyperparameter characterizing the sample. The deep learning model can comprise at least one hyperparameter characterizing the sample. The sample can comprise a photomask and the hyperparameter can define the mask type. Hyperparameters of machine learning models and/or of deep learning models are model parameters which are defined before the beginning of the training phase for the ML model or the deep learning (DL) model.

A transformation model, an ML model or a deep learning model can comprise a common encoder branch for the input data and the at least one additional parameter and can have a dedicated decoder branch for each of the additional parameters. In this regard, a generic photomask can be converted into a binary mask by a hyperparameter, for example. This is done by enabling the selected decoder branch while the other decoder branches are deactivated, i.e. are multiplied by zero, for example. In contrast to hyperparameters, the model parameters of a transformation model, of an ML model or of a DL model are determined during a learning or training process.

The at least one additional parameter increases the training complexity of the transformation model or of the deep learning model only sub-linearly since even when the at least one additional parameter is taken into account, the problems to be solved for the transformation model, the ML model or the deep learning model are similar, and so the transformation model can “reuse” parts of the model parameters already determined.

A method according to one or more embodiments can furthermore comprise the step of: training the transformation model with a training data set.

What is crucial for the prediction of the material contrast portion and/or the topography contrast portion of a tuple of measured image representations is the training of the ML or DL model, generally a transformation model, with a sufficiently large amount of training data. Particularly for deep learning architectures, which have a large number of parameters owing to their multiplicity of hidden layers, the quality and the quantity of the training data or of the training data set play a key role.

The training data set of the transformation model can comprise at least one element from the following group: a multiplicity of tuples of at least two recorded image representations of at least one sample used for training, a multiplicity of tuples of at least two recorded image representations of at least one test structure used for training, a multiplicity of tuples of at least two simulated image representations of at least one sample used for training, or a multiplicity of tuples of at least two simulated image representations of at least one test structure used for training, wherein the tuples of at least two image representations were recorded or simulated at at least partly different solid angles relative to the at least one sample and/or test structure used for training.

The simulation of the training data can comprise performing a Monte Carlo simulation of the interaction of the primary particle beam, e.g. electron beam, with the sample and an electron-optical simulation of the path of the secondary particles, e.g. the SE and BSE, from the sample to each of the at least two detectors. In order to broaden the training data generated by simulation, the sample can be subjected to a random rotation and/or a scaling. A noise contribution can be added to the input data of the simulation. Various defects of the sample can be overlaid on the input data of the simulation in a defined manner. Furthermore, the measured samples can have defects of all known kinds. A test structure can have defined defects of predefined size and/or shape. The data of the material contrast and/or of the topography contrast can be known from a calibrated test structure.

The number of tuples of measured and simulated image representations of the training data set can comprise a range of 10² to 10⁶, preferably 5·10² to 3·10⁵, more preferably 10³ to 10⁵, and most preferably 3·10³ to 3·10⁴.

A trained transformation model is provided with tuples of measured or recorded and/or simulated image representations of a sample as input into a first transformation block. The image representations of a tuple contain different portions of topography contrast and material contrast. The second transformation block of the trained transformation model outputs a transformed image representation of the sample that has a predefined ratio of topography contrast and material contrast. In particular, the transformed image representation output by the trained transformation model can have exclusively topography contrast or material contrast. Furthermore, the trained transformation model can generate two transformed sample image representations from a tuple of submitted sample image representations, wherein a first transformed image representation has exclusively material contrast portions and a second transformed image representation has exclusively topography contrast portions.

The transformation model or the deep learning model can be trained to output a tuple of transformed image representations. The tuple of transformed image representations can correspond to the tuple of the measured image representations provided to the transformation model, or can be smaller.

As specified above, a training data set for training the machine learning model or the deep learning model can comprise a multiplicity of tuples of at least two measured image representations of samples used for training and a multiplicity of tuples of at least two simulated image representations of samples used for training, wherein the tuples of measured and simulated image representations are recorded at at least partly different solid angles relative to the samples used for training. A tuple of the training data set can comprise two image representations that represent a sample region of a sample used for training from two different solid angles. The size of a tuple of the training data set can correspond to the number of detectors used for simultaneously recording image representations of a sample.

A method according to one or more embodiments can furthermore comprise the step of: recording the training data set for the transformation model.

A paradigm of machine learning (ML) is the need to have available a sufficient number of representative learning data for purposes of training the transformation model. This means that ML or DL (deep learning) methods can reliably perform the mapping of inputs onto outputs typically only for the input data for which similar learning data are present which were taken as a basis for training the transformation model.

As a result, only the image representations of samples that are contained in the training data can be simulated. If the sample is a photomask, for example, the latter can be trained exclusively by image representations of photomasks. For a generally valid transformation model of a photomask, therefore, as many different photomasks as possible should be provided in the training data, the structure or pattern elements of which correspond to the actual application. These include for example photomasks having different surface constitutions, for instance different roughnesses, and also masks with varying material composition(s) on account of contamination(s).

Since the trained transformation model is intended to be used in the context of a mask repair process, it is necessary for the training data thereof to include all photomask defects that occur in practice. Moreover, it is advantageous if the training data contain different intermediate states of defect repair. Photomasks having defined defects can be generated for training purposes on the basis of simulations. This can sometimes lead to long training periods.

It can therefore be advantageous for individual classes of photomasks (for instance binary masks, phase-shifting masks, masks for multiple exposure) to be described and trained by separate transformation models. This means that correctly training an ML model, in particular a DNN (deep neural network), typically requires consistent training data representing a one-to-one mapping of the input data onto the output data. For the field of photomasks, this means that a dedicated ML model is necessary for each individual type of mask (e.g. OMOG (Opaque MoSi On Glass), COG (Chrome On Glass), PSM (Phase Shift Mask), APSM (Alternating Phase Shift Mask) etc.). As a result, firstly the individual training phases can turn out to be shorter, and secondly the achievable accuracy for the transformed image representation(s) can be improved. Alternatively, an ML model or a DL model can be pretrained for a mask and the individual types of mask can be specified by one or more hyperparameters.

Some of the training data required can be recorded during the commissioning of a repair device. This can be done using the image representations of the mask that are obtained in the calibration phase of the repair device. The training of the ML model can also be performed in part during the calibration phase of the repair device. In order that commissioning does not take too long, the parameters of the ML model can be constantly optimized in the repair operating mode. This procedure leads to incremental learning of the ML or DL model. In this case, it can be advantageous to still keep available the original training data for the incremental learning, in order to avoid overfitting of the ML or DL model to the new data.

The topography and/or material contrast portions of measured image representation tuples can be ascertained sufficiently accurately at least ex-situ. By way of example, energy-dispersive x-ray spectroscopy (EDX) and/or an EsB (Energy-selective Backscattered) detector can be used for this purpose. For programmed defects, it is possible to have recourse to design data.

Some of the training data can be implemented with the aid of tuples of simulated image representations of the samples used for training, for instance photomasks. Unlike measured image representations, the topography contrast portion and the material contrast portion of simulated image representations are known. As a result, these are particularly well suited as training data since the fact of whether the training transformation model can realistically transform the submitted image representations can be established in a simple manner. Furthermore, image representations of less frequently used photomasks (for instance tritone phase masks) can be simulated reproducibly for training purposes. Moreover, simulations can be used to realistically generate image representations for all kinds of defects in any stage of the repair process. Measurement of thousands of image representation tuples can be avoided as a result. However, the training of the ML or DL model requires a corresponding amount of training data, which can mean that a large number of time-consuming simulations are performed. These simulations can however be performed cost-effectively at a central site with computer systems specifically optimized for this purpose.

A transformation model, an ML model or a DL model generates knowledge from experience. It learns from examples that are made available to the model in the form of training or learning data in a learning or training phase. Internal variables of the model, for example parameters of parametric mapping, can thus be allocated suitable values in order to be able to describe relationships in the training data. As a consequence, the transformation model or the ML model in general does not simply memorize the training data in the training phase, but rather identifies patterns and/or regularities in the training data. The quality of the learned relationships is typically assessed on the basis of validation data in order to assess the generalizability of the trained model to new data, i.e. data that are unknown during the training. A trained ML/DL model can be applied to an image representation tuple in order to determine the portions of topography contrast and/or material contrast in an image representation tuple that is unknown to the ML/DL model. After the completion of the training phase, a successfully trained ML/DL model, i.e. a trained ML/DL model with good generalizability, is therefore able to assess data unknown to it, i.e. unknown image representation tuples of a sample, with regard to topography contrast and material contrast.

The transformation model can comprise a generative model. The generative model can comprise a deep generative model. Hereinafter, a deep generative model is understood to be a model whose encoder and/or decoder comprise(s) more than two sequential layers. A deep generative model typically comprises three to twenty-five successively arranged layers of the encoder and/or decoder. However, it is also possible for an encoder and/or a decoder of a generative model to comprise more than 100 sequential layers.

Discriminative models can generate output data from input data; generative models can generate output data from input data and can additionally reproduce the input data at the model output.

The generative model can comprise a neural convolutional and deconvolutional network. A neural convolutional and deconvolutional network is referred to in English usage as a CNN (Convolutional Neural Network). If the input data into a generative model are image representations or image representation tuples which have a spatial structure, an expedient operation for individual layers of an encoder-decoder architecture is convolution. In this case, learnable parameters are for example the weights of the filter masks of the individual convolutional layers. In order to increase the model complexity, the convolution results of a layer are usually transformed in non-linear fashion. For this purpose, the input of each neuron, ascertained by use of discrete convolution, is converted into the output in a convolutional layer with the aid of an activation function, i.e. for instance by the application of a sigmoid function (sig(t)=0.5·(1+tanh(t/2)) or a rectified linear unit (ReLU, f(x)=max(o, x)). The concatenation of a plurality of convolutional layers each comprising an activation function allows the learning of complex patterns from the provided data for recognition tasks (referred to as: perception).

The at least two layers of the encoder can comprise two or more convolutional layers and pooling layers, and/or the at least two layers of the decoder can comprise two or more deconvolutional layers and depooling layers. In English usage, pooling layers are alternatively called “sub-sampling layers.” In the literature in the English language, depooling layers are alternatively referred to as “up-sampling layers.” As a result of the pooling effect, the number of pixels for representing an object as a feature in a layer is reduced, and at the same time the feature depth or the dimension in the encoder is increased. The feature depth is also referred to as the number of features per layer or per channel. As a result of the depooling or as a result of the increase in the sampling rate (up-sampling) as data of an object pass through the decoder, the number of pixels for representing the object as a feature in a layer is increased.

The at least two layers of the encoder can determine the information-carrying features by virtue of a reduction of a number of pixels for representing a sample image representation. The at least two layers of the encoder can determine the information-carrying features by virtue of a reduction of the spatial dimension of the sample image representations.

The sample image representations can be image representations of photomasks. The image representations of photomasks can comprise measured and/or simulated mask image representations. The measured and/or the simulated image representations can be represented for example in the form of a two-dimensional pixel matrix with greyscale values.

In order to generate simulated image representations of the sample, the latter is bombarded with primary particles and the interaction thereof with the material of the sample is calculated on a statistical basis (Monte Carlo simulation). For the example of a photomask and an electron beam as primary particle beam, the number and the angular distribution of the SE and BSE that leave the sample are thereby determined on a probabilistic basis. The interaction of the primary particles as a function of their landing energy is well understood in terms of modelling, as a result of which the intensity and the angular distribution of the secondary particles that leave the sample, for example of the SE and BSE, can be calculated reproducibly.

Input data into the input layer of a DL model, or generally into a transformation model, are images or image representations from at least two or from each of the detectors present. Analogously to a normal colour image, each detector can be regarded as a colour channel. The size of the two-dimensional pixel matrix determines firstly the complexity for recording the sample image representations or for generating the training data and for transforming the at least two image representations. The sizes of the image representations or images should be chosen at least with a magnitude such that the above-described non-local topography effects can be recognized and corrected by the DL model. The non-local effects have dimensions in the range of 5 nm to 20 nm. Image representations based on scanning regions of 200 nm×200 nm and having a pixel spacing in the range of 1 nm to 10 nm have proved to be advantageous. That is to say that the image representations of the samples typically have matrix sizes in the range of 200×200 to 20×20 pixels.

The at least one additional parameter can comprise image representation tuples recorded under different imaging conditions.

The portions of topography contrast and material contrast vary as a function of the conditions used for imaging the sample. Moreover, the imaging conditions can be adapted to the sample to be analyzed.

The imaging conditions can comprise at least one parameter from the following group: a landing energy of the primary particles on the sample, an angle of incidence of the primary particle beam on the sample, a particle current of the primary particles on the sample, an operating point of the at least one detector for detecting the secondary particles emanating from the sample, an objective setting of a particle scanning microscope (for instance a scanning electron microscope), a potential of a liner tube, a pressure to which the at least two detectors are subjected, or a temperature to which the at least two detectors are subjected. Moreover, the imaging conditions can comprise one or more of the system parameters specified above. The primary particle beam typically impinges on the sample with normal incidence. However, it is also possible to select a different angle of incidence, for instance adapted to the topography of the sample, e.g. along the edges of pattern elements of photomasks.

The landing energy of the primary particles can comprise an energy range of 2 eV to 50 keV, preferably 5 eV to 10 keV, more preferably 10 eV to 3 keV and most preferably 20 eV to 1 keV. The primary particle current can comprise a range of 1 pA to 10 nA, preferably 5 pA to 2 nA, more preferably 10 pA to 500 pA, and most preferably 20 pA to 100 pA. The at least two detectors can be arranged in a high-vacuum environment having a pressure of <10⁻³ mbar, preferably <3·10⁻⁵ mbar, and most preferably <10⁻⁷ mbar. The pressure in the high-vacuum chamber of a scanning electron microscope (SEM) can temporarily increase on account of the process gases required for a local chemical repair. The choice of usable types of detectors can be limited as a result.

At least one of the at least two detectors can comprise an energy filter. The energy filter can make it possible to apply an electric field upstream of the input of the at least one detector. Charged particles can thereby be accelerated or decelerated in the direction of the detector.

The at least one first image representation can comprise an image representation of a sample region recorded at a first solid angle by at least one first detector, and the at least one second image representation of the sample can comprise at least one second image representation of the sample region recorded at a second solid angle by at least one second detector, wherein the first solid angle is at least partly different from the second solid angle.

A sample region comprises that region of a sample surface which is scanned by a primary particle beam.

The at least two image representations can be recorded simultaneously by at least two detectors that capture at least partly different solid angles.

The at least two detectors can be arranged in a particle-optical column of a particle beam microscope. The particle beam microscope can comprise a scanning electron microscope (SEM) and the particle-optical column can comprise an electron-optical column. At least one first detector can be arranged at the output of the electron-optical column and at least one second detector can be arranged in the electron-optical column, i.e. as an in-lens detector.

The at least two recorded image representations of the sample can be recorded using at least one first detector and at least one second detector which detect secondary electrons (SE) and backscattered electrons (BSE) and an SE/BSE ratio of the at least one first detector and the SE/BSE ratio of the at least one second detector can be different.

The at least one first detector and the at least one second detector can detect different BSE distributions or different portions of the BSE distribution. The BSE portions of the at least one first detector and of the at least one second detector differ in at least one parameter from the following group: energy distribution of the BSE and solid angle distribution of the BSE. The local material composition of the sample can be ascertained from the at least two different BSE distributions. With the aid of a method according to one or more embodiments, it is possible to ascertain relative changes or differences in the material composition of a sample perpendicularly to the sample surface, i.e. in the z-direction, and/or when the primary particle beam is scanned over the sample if the latter is etched. A method according to one or more embodiments is thus directed to determining the material composition or a local change in the material composition of a scanned sample region. However, the described method is not element-specific, i.e. does not yield the element(s) of the scanned sample region.

The primary particle beam can comprise at least one particle type from the following group: electrons, ions, x-ray quanta, gamma quanta or photons from the extreme ultraviolet wavelength range.

The particles emanating from the sample can comprise at least one element from the following group: electrons, ions, x-ray quanta, and photons from the ultraviolet wavelength range, photons from the deep ultraviolet wavelength range, or photons from the extreme ultraviolet wavelength range.

The sample can comprise an element from the following group: a photomask, a stamp for nanoimprint lithography, a wafer, a MEMS (Micro-Electro-Mechanical System), a NEMS (Nano-Electro-Mechanical System) or a PIC (Photonic Integrated Circuit).

Recording the at least two image representations of the sample can comprise: irradiating a sample region with a primary focused particle beam in order to detach secondary particles that leave the sample at various solid angles. Preferably, recording the at least two image representations of the sample can comprise: irradiating a sample region with a primary focused electron beam in order to detach SE and BSE that leave the samples at various solid angles.

During the recording or before and after the recording of the at least two image representations by irradiating the sample with the primary focused particle beam, at least one precursor gas can be provided in the sample region scanned by the primary focused particle beam. The at least one precursor gas can comprise at least one element of the following group: an etching gas, a deposition gas or an additive gas.

The method according to one or more embodiments can furthermore comprise the step of: repairing at least one defect of the sample by use of a local chemical reaction that is induced by the primary focused particle beam. In the case of a focused electron beam as focused particle beam, this beam induces EBIE (electron beam induced etching) or EBID (electron beam induced deposition), depending on the precursor gas used.

Determining the topography contrast and/or the material contrast of an image representation can comprise: determining an image representation which comprises substantially no topography contrast portion.

A sample image representation which does not comprise a topography contrast portion, but rather only includes a material contrast portion, is maximally sensitive for detecting a change in the local material composition of the sample. A sample image representation which exclusively includes material contrast information is thus optimally suitable as a stop signal of a local chemical repair process.

The term “substantially” here means—as elsewhere in this application—an indication of a measured variable within the customary error limits, with metrology according to the prior art being used to measure the variable.

A computer program can comprise instructions for carrying out the method steps of any of the aspects specified above.

According to a further exemplary embodiment, the problem addressed by the invention is solved by a device according to Claim 17. In one embodiment, the device for determining a topography contrast and/or a material contrast of a sample comprises: (a) means for providing at least two image representations of the sample recorded at least partly at different solid angles relative to the sample; and (b) means for determining the topography contrast and/or the material contrast of the sample on the basis of the at least two image representations.

The means for determining can be configured for applying a decoupling model to the at least two image representations for determining the topography contrast and/or the material contrast of the sample.

The device can furthermore comprise at least one first detector and at least one second detector for providing the at least two image representations, wherein the at least one first detector and the at least one second detector each detect secondary electrons (SE) and backscattered electrons (BSE) and wherein an SE/BSE ratio of the at least one first detector and the SE/BSE ratio of the at least one second detector are different from one another. The trajectories or paths of the SE and/or BSE can be influenced by the objective lens that focuses the primary particle beam. If this is the case, the trajectories of the SE and/or BSE are greatly dependent on the kinetic energy of the secondary particles.

The first detector can be arranged in an electron-optical column of the device, and/or the second detector can be arranged in the electron-optical column of the device. The first detector can be arranged nearer the sample than the second detector. This means that both detectors can be embodied as in-lens detectors.

The solid angles of the at least two detectors that record the two image representations can partly overlap or coincide. One detector can therefore partly shade the other detector. Moreover, it is possible for components of a repair device to limit the viewing angle or solid angle of one or both detectors vis-à-vis the sample. Partial shading can occur in particular for detectors incorporated in a particle-optical column of a repair device. Moreover, the solid angles that the individual detectors “see” or image can be dependent on the system settings of the repair device, for example the magnitude of the electric and magnetic field generated by the objective lens of the repair device. Moreover, it is possible to record two or more image representations using one detector, a different part of the detection area of the detector being covered for each image representation.

The second detector can comprise an energy filter. The energy filter generates an adjustable electric field upstream of the input of the detector. Charged secondary particles can thus be accelerated or decelerated in a defined manner in the direction of the detector. The energy filter of the second detector makes it possible largely to separate SE and BSE.

The energy filter can be designed to generate a potential in a range of ±0.05 kV, preferably ±0.2 kV, more preferably ±0.5 kV, and most preferably ±2.0 kV. The energy filter can have a filter width of <400 eV, preferably <200 eV, and most preferably of <100 eV, given a pass energy of 50 eV, preferably 200 eV, more preferably 500 eV, and most preferably 2000 eV.

The device can be configured to perform the method steps according to any of the aspects specified above.

The means for applying a decoupling model can comprise a dedicated hardware component for analyzing the at least two image representations of the sample. The dedicated hardware component can comprise at least one element from the following group: an application-specific integrated circuit (ASIC), a field programmable gate array (FPGA), a programmable logic circuit (PLD, programmable logic device), and a graphics processor unit (GPU).

Many machine learning methods can be optimized for the use of specific computing units in order to considerably accelerate their implementation. In this case, especially graphics processor units (GPUs) have proven to be advantageous for DNN. The calculable image representation size is typically limited by the available main memory of the GPU. However, the image regions (FOV, Field Of View) customary in the image representations of photomasks are sometimes significantly larger than a size that can be handled by DNN with current GPUs. This problem can be solved by dividing the image representation region to be calculated into partial regions. In this case, the partial regions of an image representation are calculated individually. This applies both to the training and to the application of the transformation model to an image representation to be analyzed or to be determined. The calculated partial image representations are subsequently combined to form an overall image or an overall image representation.

The device can furthermore comprise: means for training a transformation model with a training data set.

The device can moreover comprise a liner tube, via which the potential of the electrons within the column can be changed by a predefined value.

Finally, the device can comprise a gas feed system and at least three gas storage containers. At least one etching gas, at least one deposition gas and at least one additive gas can be stored in the gas storage containers. The gas feed system is designed to provide the precursor gases stored in the gas storage containers in an adjustable amount in a sample region scanned by the primary particle beam.

### BRIEF DESCRIPTION OF DRAWINGS

The following detailed description describes currently preferred exemplary embodiments of the invention with reference to the drawings, in which

FIG. 1 illustrates a schematic energy spectrum of the electrons generated by an electron beam incident on a sample;

FIG. 2 presents the solid angle distributions of backscattered electrons (BSE) for five different elements having different atomic numbers for two kinetic energies of the primary electron beam;

FIG. 3 shows a schematic image representation of a mask segment having a high portion of topography contrast and a low portion of material contrast;

FIG. 4 presents the mask segment from FIG. 3 in an image representation characterized by a low portion of topography contrast and a high portion of material contrast;

FIG. 5 presents a coordinate system spanned by the contributions of topography contrast and material contrast of an image representation;

FIG. 6 illustrates the coordinate system from FIG. 5 with the image representations from FIGS. 3 and 4 plotted therein;

FIG. 7 schematically presents the reconstruction of a material contrast portion and a topography contrast portion from at least two sample image representations with the aid of a decoupling model;

FIG. 8 shows a schematic section through a column of a scanning electron microscope, in which column two detectors are arranged at different distances from the sample;

FIG. 9 schematically illustrates a section through the solid angle distributions of the secondary particles that emanate from a sample and reach the two detectors from FIG. 8;

FIG. 10 presents in the upper partial image a schematic section through a mask with a ruthenium substrate and a tantalum pattern element and illustrates in the lower partial image signals of the two detectors from FIG. 8 for simulated line scans along the edge of the pattern element, and presents a signal which has been reconstructed from the signals of the two detectors and which substantially only contains material signal information;

FIG. 11 presents the signal from FIG. 10, which signal has been reconstructed from the signals of the two detectors from FIG. 8, as vector addition of the two signals;

FIG. 12 presents a flow diagram of a pixel-by-pixel reconstruction of the material contrast and/or topography contrast signal portions from at least two determined intensities of the detectors from FIG. 8;

FIG. 13 illustrates a flow diagram for optimizing the parameters of an empirical model with the aid of a calibrated test sample;

FIG. 14 schematically shows a generic deep learning model in the form of a U-Net architecture;

FIG. 15 illustrates the U-Net architecture from FIG. 14 with input data for solving the problem of the present application and output data which are present in the form of a material contrast image and a topography contrast image;

FIG. 16 schematically illustrates a GAN (generative adversarial network) for generating SEM images for training purposes;

FIG. 17 schematically illustrates a GAN for adapting the parameters of a simulation tool for performing Monte Carlo simulations for generating SEM images for training purposes for a generative deep learning model;

FIG. 18 presents test structures for a photomask with defined defects for generating training data;

FIG. 19 presents LS (lines and spaces) structures with defined defects for generating training data;

FIG. 20 illustrates contact hole structures for generating training data;

FIG. 21 shows the contact hole structures from FIG. 20 with defined defects;

FIG. 22 indicates a table summarizing the variation ranges of the defined defects from FIGS. 18 to 21;

FIG. 23 schematically illustrates the operation of a first embodiment of a machine learning model;

FIG. 24 schematically illustrates the operation of a second exemplary embodiment of a machine learning model (ML model);

FIG. 25 schematically illustrates the operation of a third exemplary embodiment of an ML model;

FIG. 26 schematically illustrates the training of the ML model from FIG. 23;

FIG. 27 illustrates a schematic section through a device which can perform a method according to the invention and a local chemical sample repair process;

FIG. 28 indicates a flow diagram of a method for determining a topography contrast portion and/or a material contrast portion of an image representation of a sample; and

FIG. 29 schematically shows an exemplary transformation model having four transformation blocks.

### DETAILED DESCRIPTION

Currently preferred embodiments of a method according to the invention and of a device according to the invention for determining a topography contrast portion and/or a material contrast portion of an image representation of a sample are explained in more specific detail below. However, the method according to the invention is not restricted to the photomasks as sample examples discussed below. Rather, the method according to the invention and the device according to the invention can be used for determining the topography contrast portion and material contrast portion of any microstructured samples. A device according to the invention is discussed below on the basis of the example of a modified scanning electron microscope. However, a device according to the invention is not restricted to the exemplary embodiment explained. Besides electrons, it is also possible to use other charged particles and/or high-energy photons for determining the topography contrast portion and material contrast portion of a sample. Furthermore, the method according to the invention is explained below on the basis of the example of two detectors that detect secondary particles from different solid angles. However, the method explained is not restricted to the use of two detectors. Rather, this method can be used with one detector and advantageously for three or more detectors. Moreover, besides the signal originating from a plurality of detectors, a method according to the invention can also make use of the detected current flow which, in the case of electrically conductive samples, flows away via the latter, in order to process the electrical charge instantaneously present on a sample with one another in such a way as to obtain more or more precise information about the sample properties.

The interaction between particle radiation and a sample is illustrated below on the basis of the example of the action of an electron beam on the sample. The incidence of a focused electron beam that scans a region of the sample is described in detail. This sample region is called the field of view (FOV). During the irradiation of a sample with the electrons of an electron beam, the electrons interact with the sample. The process of interaction of the incident electron beam with the atoms of the sample generates free electrons in the sample. Some of the electrons generated in the interaction process can leave the sample surface and can be detected by one or more detectors and used for generating an SEM (scanning electron microscope) image of the sample surface.

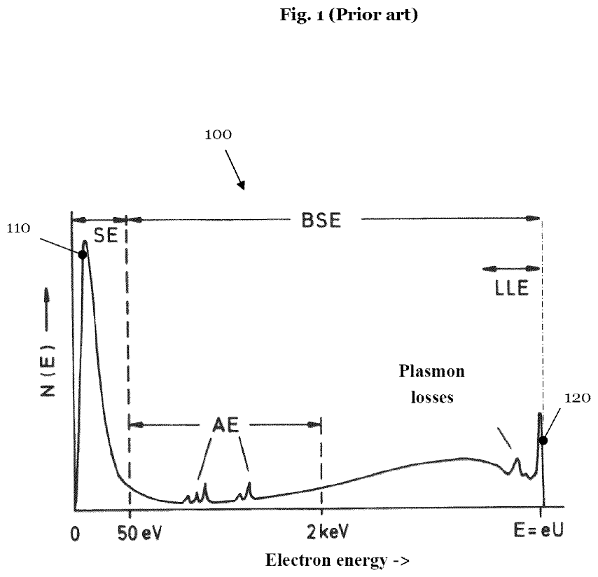

The diagram 100 in FIG. 1 schematically shows the energy spectrum of the electrons generated by an electron beam in a sample. This figure can be taken from the book “Scanning Electron Microscopy” by L. Reimer. The energy spectrum of the electrons emitted by a sample is classified in two main groups. Low-energy electrons with a kinetic energy of up to 50 eV (electronvolts) are called secondary electrons (SE). All other generated electrons having a spectral energy distribution ranging from 50 eV substantially to the kinetic energy of the electrons of the incident electron beam (E=e·U, E is the landing energy of electrons, e denotes the elementary charge and U denotes the potential difference traversed by electrons of the electron beam for their acceleration) are referred to as backscattered electrons (BSE).

If the surface of a sample has no surface charges, the energy spectrum of the secondary electrons exhibits a distinct material- and/or topography-specific peak 110 (SE peak 110) in the range of a few volts. In the energy range of approximately 50 eV to approximately 2 keV, material-specific peaks may likewise occur in the spectrum of backscattered electrons, caused by Auger electrons (AE). At the upper end of the energy spectrum of backscattered electrons there is an elastic peak 120 caused by electrons that are reflected from the sample surface substantially with the kinetic energy of the incident electrons, i.e. the landing energy thereof (BSE peak 120). Below this peak 120 there is the adjacent so-called LLE (Low Loss Electron) range, which includes backscattered electrons, the energy of which is typically 10 eV to 100 eV lower than the kinetic energy of the incident electrons. The LLE range also comprises the range of plasma excitation (plasmon losses), so that in this spectral range relatively few backscattered electrons leave the sample surface.

The diagram 100 reveals that a detector without an energy filter always detects both SE and BSE. It is furthermore evident from FIG. 1 that the low-energy SE are far more numerous than the BSE exhibiting greater kinetic energy. The SE are predominantly emitted at local raised parts of the sample, for instance along edges. Therefore, these appear brighter than a sample surface in a sample image representation. The SE therefore principally contribute to the topography contrast of a sample image representation recorded using a focused electron beam.

Generation of an electric field of corresponding polarity makes it possible for the SE to be decelerated to such an extent that they can no longer reach a detector. The intensity of an SEM image filtered in this way becomes drastically lower as a result, and indeed the numerous SE no longer contribute to image generation. However, the resulting image representation still includes the broad spectrum of the BSE and the peak 120 of substantially elastic scattering.

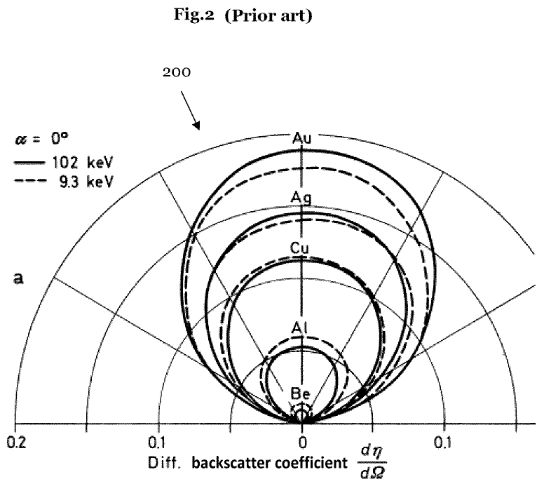

The diagram 200 in FIG. 2 shows the differential backscatter coefficient of the BSE generated by various elements for two different kinetic energies of the electrons of the incident electron beam. The incident primary electrons (PE) are elastically scattered in the field of the atomic nuclei. The deflection of the primary electrons at the atomic nucleus is all the greater, the higher their positive charge. FIG. 2 presents the distributions for the elements beryllium (Be), aluminium (Al), copper (Cu), silver (Ag) and gold (Au) for two primary energies. The proportion of substantially elastically backscattered electrons, i.e. the height of the BSE peak 120, depends on the material of the sample that is irradiated by the primary focused electron beam.

As illustrated in FIG. 2, the angular distribution of the radiant intensity of the BSE approximately follows a cosine distribution. The present application makes use of this regularity in order to generate image representations of samples which have a predefined ratio of topography contrast and material contrast. In particular, this regularity is used to generate image representations of samples which have substantially exclusively material contrast. The angular distribution of the BSE hardly changes as a function of the kinetic energy of the PE.

An empirical model is described below as a first exemplary embodiment for determining a topography contrast contribution and a material contrast contribution of a sample image representation.

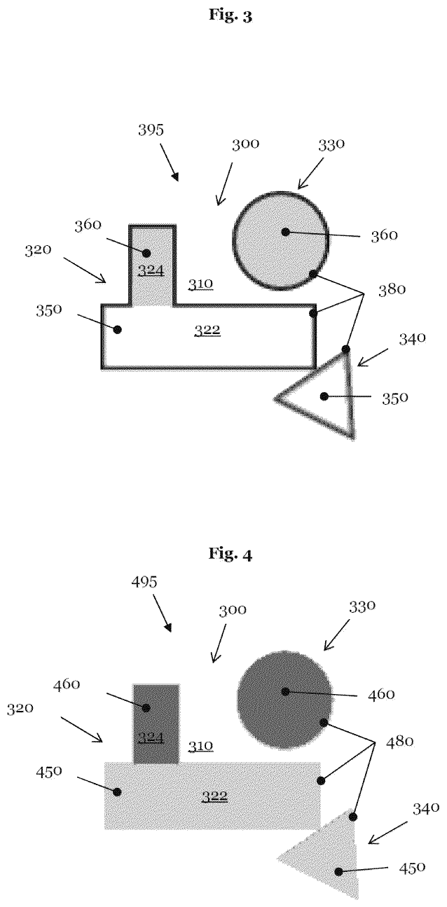

The image representation 395 in FIG. 3 schematically shows a segment of a sample 300. The sample 300 can be a photolithographic mask 300. Three pattern elements 320, 330 and 340 are arranged on the mask substrate 310 of the exemplary mask 300. The pattern element 320 comprises two interconnected rectangular structures 322 and 324 interconnected at one side. The second pattern element 330 has a circular surface and the third pattern element 340 has a triangular structure. The part 322 of the first pattern element 320 and the triangular pattern element 340 comprise a first material 350. Furthermore, the round pattern element 330 and the part 324 of the first pattern element 320 comprise a second material composition 360. In the example indicated in FIG. 3, the first material 350 results in a lower intensity in the image representation 395, represented by the lighter grey shade, compared with the second material 360, which is depicted by a somewhat darker grey shade in the image representation of the mask 300. The conclusion that can be drawn from this is that the material 360 has a higher atomic number than the material 350 of the mask 300. The first part 322 of the first pattern element 320 and the second pattern element 330 can be deposited onto the mask substrate 310 with the aid of a particle beam-induced deposition process, for example in order to produce a missing pattern element 330 and/or a partly missing pattern element 324.

The wide dark edge 380 of the pattern elements 320, 330, 340 of the mask 300 makes it clear in the image representation 395 that the latter has a large topography contrast contribution 380 besides the material contrast 350, 360. A comparatively large topography contrast contribution 380 of the image representation 395 indicates that the detector which has detected the SE and BSE which were taken as a basis for generating the image representation 395 ought to have a larger angle relative to the beam axis of the primary electron beam.

In FIG. 3, as in the subsequent FIGS. 4 to 6, it should be noted that the image representations do not present measurement data of photomasks, but rather merely serve to elucidate the principles of the present application. Furthermore, it should be pointed out that in the illustrative FIGS. 3 to 6 light and dark respectively correspond to dark and light in the subsequent figures. This interchange is undertaken here merely for reasons of easier illustration on a white background.

The image representation 495 in FIG. 4 repeats the image representation 395 from FIG. 3, but with a different material contrast 450, 460 and topography contrast 480 and the ratio thereof. The edge 480 or the edges 480 are present to a significantly lesser extent in the image representation 495 compared with the image representation 395 in FIG. 3. Conversely, the difference in the grey levels 450, 460 is significantly more pronounced, once again compared with the image representation 395 in FIG. 3. The SE/BSE ratios of the image representations 395 and 495 are distinctly different. This means that a comparatively smaller angle of the detector with respect to the beam axis of the primary electron beam is assumed when the image representation 495 is recorded, compared with when the image representation 395 is detected.

A procedure in which the two image representations 395 and 495 recorded at different angles or solid angles relative to the beam axis of the primary particle beam are considered in combination, i.e. are linked with one another in a suitable manner, makes it possible to eliminate the edge 380, 480 of the pattern elements 320, 330, 340 of the mask 300, i.e. the topography contrast contribution in the image representations 395, 495. An image representation which has substantially only material contrast can be generated as a result.

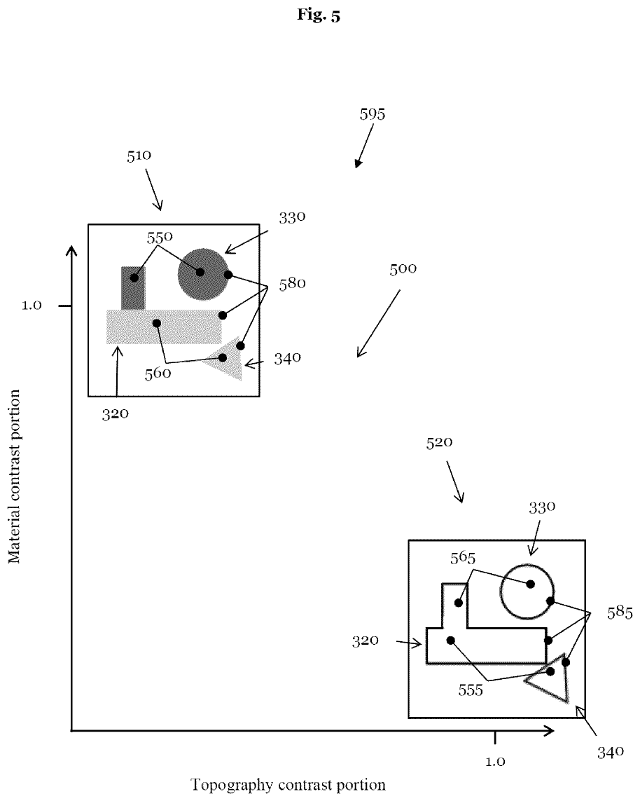

The diagram 595 in FIG. 5 presents a coordinate system 500 spanned by a topography contrast component and a material contrast component of a sample image representation. This means that the axes of the coordinate system 500 totally separate the topography contrast content or the topography contrast intensity and the material contrast content or the material contrast intensity. In the exemplary coordinate system 500 in FIG. 5, the topography contrast is plotted on the abscissa and the material contrast is plotted on the ordinate. The partial image 520 illustrates the segment of the mask 300 when exclusively the topography contrast intensity 585 of the pattern elements 320, 330, 340 of the mask 300 contributes to the generation of the image representation. The contribution stemming from the different material compositions 350, 360 of the pattern elements 320, 330, 340 of the mask 300, which contribution is illustrated by different grey levels in the image representation 395 in FIG. 3, has disappeared.

At this point attention is again drawn to the schematic character of the image representations 395, 495, 510 and 520. In a real image representation of the pattern elements 320, 330, 340 present on the mask substrate 310, their edges would appear lighter, compared with the surface of the mask substrate 310 and the surfaces of the pattern elements 320, 330, 340.

The partial image 510 illustrates the segment of the mask 300 when exclusively the material contrast intensity 550, 560 of the mask 300 contributes to the generation of the image representation. The edges 580 of the pattern elements 320, 330, 340 are no longer highlighted by a change in intensity in the partial image 510. A portion which the topography of the mask 300 contributes to the intensity distribution of the image representation of the partial image 510 is no longer visible in the partial image. This means that the partial image 510 has no topography contrast contribution. Conversely, the different material compositions 550, 560 of the pattern elements 320, 330, 340 of the mask 300 become optimally visible in the partial image 510.

The partial images 510 and 520 show the segment of the mask 300 when only the topography of the mask 300 (partial image 520) or the material composition thereof (partial image 510) contributes to the image representation of said mask. Measuring the partial images 510 and 520 is difficult. It is not possible to select the SE that emanate from the mask 300 and predominantly carry topography information, since the contribution of the high-energy BSE to image generation cannot be eliminated. In the partial image 520 in the diagram 595, the topography of the sample, i.e. of the mask 300, is indicated as an image representation of the edge 380 and thus the edges of the pattern elements 320, 330, 340. However, the edge 380 of the pattern elements 320, 330, 340 is identical to the height profile of the mask 300, and so the partial image 520 presents the topography or the height profile or the profile of the change in height of the mask 300.

The material contrast portion 450, 460, 550, 560 during the creation of an image representation of the mask 300, or more generally of a sample 300, can be increased by use of the detector that detects the secondary particles being arranged around the primary particle beam. Moreover, by generating an electric field having a potential difference of 50 eV of corresponding polarity upstream of the detector, it is possible to prevent SE having a kinetic energy of less than 50 eV from passing into the detector. Furthermore, a stronger electric field makes it possible to prevent some of the low-energy BSE from entering the detector. However, it is technically not possible to divide the spectrum of the secondary particles in such a way that exclusively the BSE of the peak 120 reach the detector. A wide background of partly inelastically scattered BSE prevents the recording of a sample image representation which reproduces only material contrast intensity. Moreover, BSE with a decreasing polar angle are subject to increasingly larger shading effects which produce a topography contrast contribution in the corresponding image representation.

It is possible, however, to generate the partial images 510 and 520, representing pure topography contrast and pure material contrast, by performing corresponding simulations. In Monte Carlo simulations, the interaction of the primary particles (PE) with the material of the mask substrate 310 and the material composition and also the topography of the pattern elements 320, 330, 340 is simulated on a statistical basis. From the results of these simulations, it is possible to generate images to whose intensity distribution a contribution is made only by the SE that carry topography contrast information. Furthermore, from the simulation data, it is possible to generate image representations to whose generation a contribution is made only by BSE of the peak 120. In the simulation, the angular distribution of the BSE that ought to contribute to image generation can be selected in a simple manner. These complex simulations can be performed by a computing unit specifically designed for this purpose.

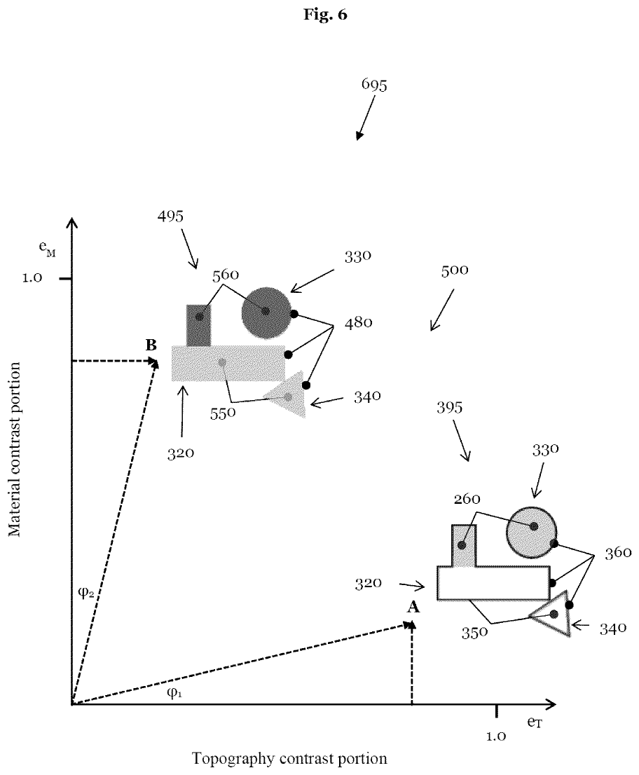

The diagram 695 in FIG. 6 again presents the coordinate system 500 from FIG. 5. The image representations 395 and 495 of the segment of the mask 300 are now plotted in this coordinate system 500. As explained in the context of FIGS. 3 and 4, the image representation 395 has a large contribution of the mask topography 380 to the intensity distribution of the image representation 395. The image representation 395 therefore lies in the vicinity of the axis that describes the contribution of the topography to the intensity distribution of the image representation 395. By contrast, in the image representation 495, the material contrast 450, 460 predominantly contributes to the intensity distribution of the image representation 495. Consequently, the image representation 495 lies in the vicinity of the axis of the coordinate system 500 that describes the material contrast contribution to the image generation.

From two image representations that represent a sample 300, for instance the photomask 300, recorded at different solid angles, the contributions of the sample topography and the sample material can be extracted. A photomask 300 has pattern elements 320 and 350 and hence a non-planar surface. In the case of a sample having a plane surface, the different solid angles must comprise different angles in relation to the primary beam.

In the coordinate system 500, the image representations A, 395, and B, 495 can be represented by a linear combination of vectors e_{T} of the topography contrast portion axis (T-axis) and e_{M} the material contrast portion axis (M-axis):

$$A = {a}_{1} \cdot {e}_{T} + {a}_{2} \cdot {e}_{M}$$

$$and$$

$$B = {b}_{1} \cdot {e}_{T} + {b}_{2} \cdot {e}_{M} ,$$

or in matrix notation

$$( \begin{matrix}A \\ B\end{matrix} ) = ( \begin{matrix}{a}_{1} & {a}_{2} \\ {b}_{1} & {b}_{2}\end{matrix} ) \cdot ( \begin{matrix}{e}_{T} \\ {e}_{M}\end{matrix} ) = T \cdot ( \begin{matrix}{e}_{T} \\ {e}_{M}\end{matrix} )$$

After the parameters or coefficients a₁, a₂, b₁ and b₂ have been determined, the topography contrast and material contrast contributions of the image representations A or 395 and B or 495 can be ascertained. The two image representations A or 395 and B or 495 yield four variables A_{T}, A_{M}, B_{T} and B_{M}, which make it possible to define the four parameters or coefficients a₁, a₂, b₁ and b₂ of the transfer matrix T.

Alternatively, the image representations A or 395 and B or 495 can be represented by a rotation of the coordinate system by an angle φ₁ and φ₂ on the T-axis or M-axis thereof. The rotation matrix is given by:

$$T = ( \begin{matrix}cos {φ}_{1} & sin {φ}_{1} \\ cos {φ}_{2} & sin φ\end{matrix} )$$

After the angles φ₁ and φ₂ of rotation have been ascertained, the contributions of the topography 380, 480 and of the material 350, 360, 450, 460 of the sample 300 can be ascertained.

As explained above, one of the aspects of the present application is to use a change in the material contrast contribution of a sample image representation 395, 495 for deriving a stop signal for a local chemical repair process of a sample defect. For this purpose, it is advantageous to use the image representation 495 having the larger material contrast contribution. The signal change upon the detection of a transition of the primary particle beam from a first sample layer into a second sample layer having a different material composition is larger than for the second image representation 395. This makes it possible to ascertain the stop time of the local chemical reaction with greater precision. The image representation 495 that satisfies this precondition is the image representation that was recorded by a detector having a large portion of BSE reflected substantially antiparallel to the primary particle beam. If the difference in the material contrast portion of the image representation 495 is not sufficient for this purpose, the methods described in the present application make it possible to generate sample image representations which present substantially exclusively the material contrast portion.

The above-outlined summary of the decoupling into material contrast and topography contrast portions by use of linear algebra is idealized. It is preferred to use more complex empirical models or a transformation model for this purpose.

The theoretical principles of the present application are briefly outlined below. The basic assumption thereof is that an image representation of a sample or the image signal thereof for a non-charged sample on each detector is constituted by a combination of (a) topography contrast (referred to as: z-map or “height map”) and (b) material contrast (element composition or material composition, crystal structure, etc.).

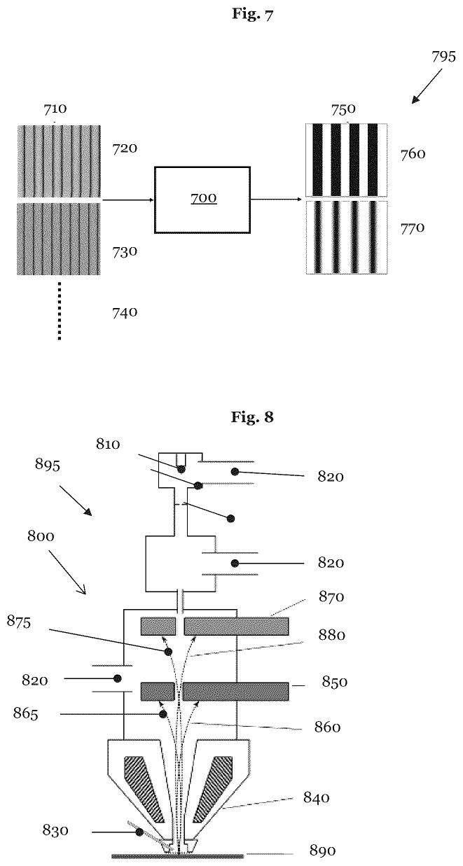

The diagram 795 in FIG. 7 illustrates the process of separating material contrast and topography contrast portions in image representations with the aid of a decoupling model 700. The decoupling model 700 can comprise an empirical model and/or a transformation model. Images 720, 730, optionally 740 are provided as input data 710 to the decoupling model 700 and the decoupling model 700 transforms these images into a material contrast image 760 and a topography contrast image or height profile image 770 and provides them at its output 750.

In order to record the images 720, 730, 740, a primary electron beam can be scanned over a sample and the secondary particles emanating from the sample can be recorded by two or more detectors. If a focused electron beam, as an example of a charged focused particle beam, is scanned over the sample, electrons, as an example of secondary particles, with different energy and angular distributions are generated with a certain probability at each scanning point. These distributions Ψ or emission distributions Ψ are dependent on the local topography and the material composition of the sample and are energy-dependent:
Ψ(E,ϕ)

The diagram 895 in FIG. 8 schematically shows a section through a column of a scanning electron microscope (SEM) 800. The SEM 800 comprises an electron source 810 and connections 820 for generating a reduced pressure or vacuum in the column of the SEM 800. Furthermore, the SEM 800 comprises a gas providing system 830 for providing a precursor gas on a sample 890 or a photomask 890. The objective 840 or the objective lens 840 focuses the electron beam or the primary electron beam, which is not depicted in FIG. 8, onto the sample 890. Some of the secondary particles generated by the sample 890 are recorded by the first detector 850 and the second detector 870. Via the trajectory 865, predominantly secondary electrons (SE) 860 reach the first detector 850. Via the path 875, principally backscattered electrons (BSE) 880 impinge on the second detector 870.

As illustrated in FIGS. 8 and 9, each detector 850, 870 detects secondary particles, i.e. SE 860 and BSE 880, from a different segment of these distributions with the acceptance functions D_{1,2}(E,ϕ), i.e. a dedicated angular range as a function of the kinetic energy of the secondary particles. In this case, D_{1,2}(E, ϕ) assumes only the values 0 or 1, namely the value 0 if the secondary particle does not impinge on the corresponding detector 850, 870, and the value 1 if the secondary particle impinges on the detector 850 or 870. The signals I_{1,2} of the two detectors 850, 870 are then the integral from the acceptance function D_{1,2}(E, ϕ) multiplied by the emission distribution Ψ(E, ϕ):

$${I}_{1 , 2} = {\int }_{0}^{e \cdot U} {\int }_{- \frac{π}{2}}^{+ \frac{π}{2}} {D}_{1 , 2} ( E , ϕ ) Ψ ( E , ϕ ) d E d ϕ ,$$

this involves integration firstly over a semicircle over the sample surface and the kinetic energy of the secondary particles, which ranges from 0 to Eₘₐₓ=e·U. The emission angle distribution is principally dependent on the landing energy of the electrons of the primary electron beam, with minor dependence anyway on the spot size and the convergence angle of the primary electron beam. In the example illustrated in FIG. 8, the detectors 850 and 870 are arranged rotationally symmetrically around the electron beam.

The diagram 995 in FIG. 9 presents the detector acceptance ranges for SE 860 and BSE 880 of the arrangement of the two detectors 850 and 870 from FIG. 8. The circle 910 corresponds to the angular distribution of the SE 860 and the highlighted regions 920 and 930 indicate the angular acceptance ranges of the detectors 850 and 870. The circle 950 illustrates the angular distribution of the BSE 880 and the segment 960 (970) illustrates the acceptance angle range of the detector 850 (870). The detector acceptance functions D_{1,2}(E, ϕ), i.e. the segments 920, 930, 960 and 970, are dependent on the landing energy of the primary electrons on the sample, the working distance (i.e. the distance between the sample 890 and the objective 840), the convergence angle of the primary electron beam, and of course the positions of the detectors 850 and 870 within the column of the SEM 800. The first detector 850, the distance of which from the sample 890 is smaller than the distance of the second detector 870, “sees” secondary particles emitted by the sample 890 at a larger polar angle, compared with the second detector 870. The detector acceptance functions D_{1,2}(E, ϕ) can be determined with the aid of electron-optical simulations.

FIG. 9 reveals that the detectors 850, 870 record different portions of BSE 880 and SE 860 and also different polar angle ranges 920, 930, 960, 970. Therefore, with two or more detectors 850, 870 it is possible to approximate the local emission distribution Ψ(E, ϕ) and thereby obtain information about the topography and material composition of the sample 890.

In the examples described below, the emission distribution is not determined, rather either an empirical model is adapted to the sample to be analyzed and is subsequently parametrized or a trained transformation model is used to separate material contrast and topography contrast portions of one or more image representations.

Firstly, a description is given of the process of determining a local material signal, i.e. a local image representation of the sample 890, which has substantially material contrast portions. In a binary sample 890, such as a binary photomask, for instance, it is merely necessary to distinguish between the material of the absorbing pattern elements and the mask substrate.

In a first embodiment, for ascertaining a local material signal with the aid of the detectors 850 and 870 at a point, the secondary particles emitted by the sample 890, or the mask 890 in the example under discussion, are recorded, i.e. detector signals for determining a local material signal of the mask 890 are recorded pixel by pixel. The signals from two detectors 850, 870, in the general case signals from k detectors (k≥2), recorded at a point (i,j) of the sample 890, are processed by use of a function in order to generate a material signal S(i,j) of the sample 890 at the location (i,j). In the simplest form, a linear combination of the different detector signals Iₖ can be used. However, it is also possible to use other functions from the signals Iₖ of the k detectors. For example, new signal features of the k detectors could be generated as products of individual detector signals.

If the empirical model has a linear combination of the signals Iₖ of the detectors 850 and 870, the material signal, the material contrast signal or the material contrast signal function S(i,j) of the sample 890 at the location (i,j) has the form (k=2):

$$S ( i , j ) = {\sum }_{k} {a}_{k} {I}_{k} ( i , j ) + {a}_{0} ,$$

where a₀ is a normalization constant.

The coefficients of the function or the parameters of the empirical model can be calibrated such that the function or the empirical model assumes the value 0 for the absorbing material of the pattern elements and the value 1 for material of the mask substrate, or vice versa.

An empirical model for a specific material combination of the sample 890 and a specific operating point can be found by way of the following procedure:

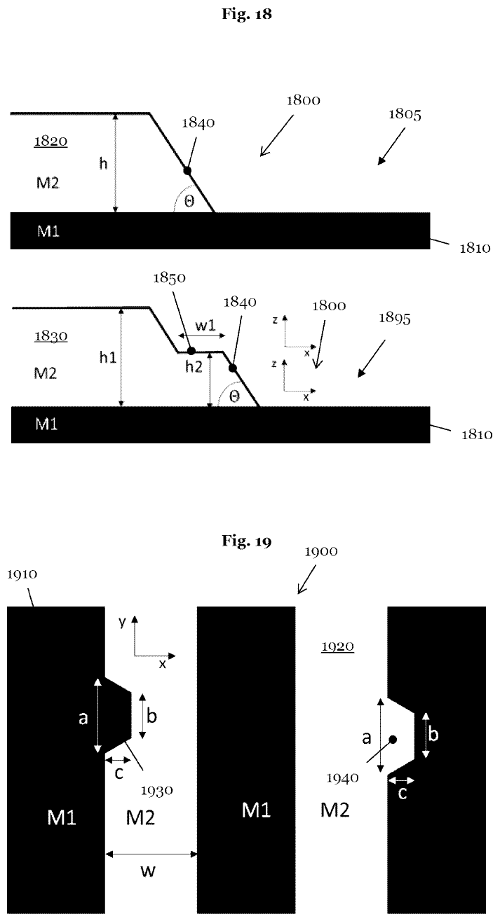

In the first step, recording is carried out by each of the k detectors at different locations of a calibrated test sample comprising at least one calibrated test structure, having absorbing test structures T_{A} and mask substrate material T_{S}. The test structures T_{A} of the calibrated test sample can comprise pattern elements having different dimensions. In addition, the test structures T_{A} can include, e.g., line structures with varying spacings, holes or contact holes and islands of varying size, and also programmed defects. Examples thereof are indicated in FIGS. 18 to 22.

For the calibrated test sample having at least one calibrated test structure T_{A} the material information M(i,j) is known on the basis of the calibration process carried out. This means that M(i,j) has the value 0 in regions of the material of the test structures TA and the value 1 in regions of the material of the mask substrate T_{S}.

However, it is also possible to generate the image representations of a calibrated test structure by performing simulations on the basis of the calibrated test structure. As already explained above, the simulations include firstly performing Monte Carlo simulations of the interaction of the primary beam with the at least one test structure T_{A} of the calibrated test sample and secondly performing an electron-optical simulation of the trajectories of the secondary particles to each of the two detectors 850, 870 of the SEM 800 in the general case of the k detectors of the detector configuration.

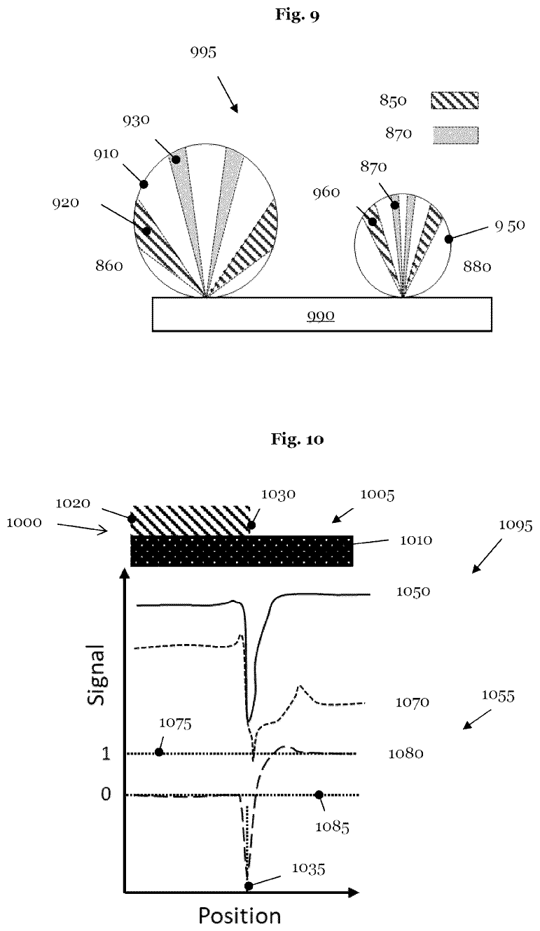

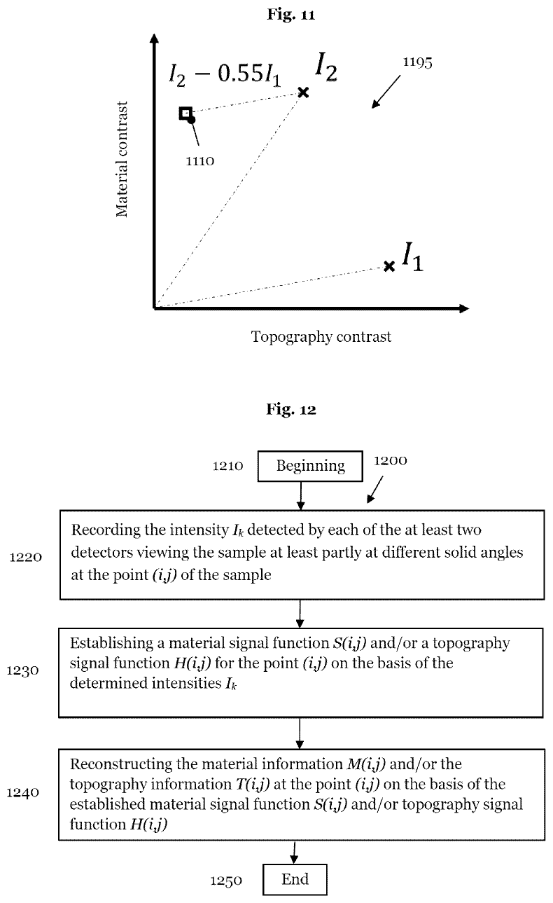

The diagram 1095 in FIG. 10 shows a schematic section through a sample 1000 in the upper partial image 1005. The sample 1000 comprises a ruthenium (Ru) substrate 1010 and a pattern element 1020 containing tantalum (Ta). In the simulation, depicted in the lower partial image 1055, a line scan is performed on the Ru substrate 1010 along the Ta edge 1030 with a landing energy of the primary electrons of 400 eV. The signal or the intensity of the first (second) detector 850 (870) is depicted as a solid line 1050 and respectively as a dashed line 1070 in FIG. 10. The curve 1080 represents the material contrast signal 1080 reconstructed from the signals of the first detector 850 and the second detector 870. The reconstructed material contrast signal 1080 follows the material change tantalum->ruthenium with a reduced influence of the topography of the sample 1000. The dotted horizontal lines 1075 and 1085 are normalizations for the material contrast of the Ru substrate 1010 and the Ta pattern element 1020. As illustrated by the vertical dotted line 1035, from the reconstructed signal 1080, which corresponds to a topography change, but in the example in FIG. 10 accords with the location of the change in the material composition Ta->Ru, the determination can take place with great accuracy.

The diagram 1195 in FIG. 11 represents the reconstruction of the material contrast signal 1080 from FIG. 10 as vector addition in a coordinate system spanned by the topography contrast and the material contrast of the signals Iₖ of the detectors 850 and 870. In the example presented in FIGS. 10 and 11, the reconstructed material contrast signal 1080 results from the subtraction of 55% of the signal of the first detector 850 from the signal of the second detector 870. This is symbolized by the point 1110 in the diagram 1195.

Alternatively, one of the k detectors for recording test images can be equipped with a screening grid. This is ideally the detector which is at the greatest distance from the sample 890. This is the second detector 870 in the example illustrated in FIG. 8. It is thereby possible at each point additionally to record an EsB (Energy-selective Backscattered) image with an activated screening grid. This image can then be taken as a good approximation of the material signal M(i,j). After the parameters of the empirical model have been defined, however, it is no longer necessary to use a screening grid. The instabilities of the primary electron beam that are possibly caused by the high voltage required for the screening grid can be avoided as a result.

The second step involves minimizing the absolute value of the difference between the material signal of the sample 890 S(i,j) and the material contrast signal or the material information of the calibrated test structure M(i,j) by varying the parameters of the material contrast signal or the material signal function S(i,j) of the empirical model. A person skilled in the art can achieve this by trial and error in straightforward cases. In any or a general case, the parameters of the empirical model can be determined by the use of known optimization methods:

$$min \vert S ( i , j ) - M ( i , j ) \vert$$

By minimizing the absolute value of the difference between the topography signal of the sample 890 H(i,j) and the topography information of the test structure T(i,j)

$$min \vert H ( i , j ) - T ( i , j ) \vert ,$$

it is possible to determine the height profile of the sample 890, 1000 or a height profile map substantially without the influence of the material contrast.

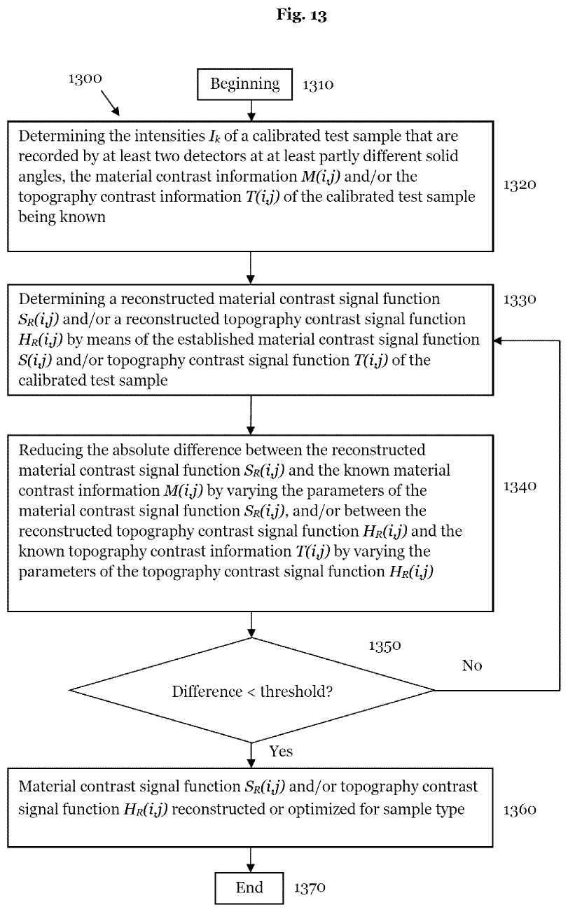

FIG. 12 presents a flow diagram 1200 summarizing a pixel-by-pixel reconstruction of topography and material contrast contributions from at least two image representations. The method begins at 1210. In the first step 1220, the intensities Iₖ are determined by each of at least two detectors viewing the sample at at least partly different solid angles at a point (i,j) of the sample 890, 1000. The determination can be effected by measurement and/or simulation. Step 1230 then involves establishing a material signal function S(i,j) and/or a topography signal function H(i,j) for the point (i,j) on the basis of the determined intensities Iₖ. Step 1240 subsequently involves reconstructing—on the basis of the established material signal function S(i,j) and/or topography signal function H(i,j)—the local material contrast portion M(i,j) or the local material information and/or the local topography contrast portion T(i,j) at the point (i,j) of the sample 890, 1000. For the reconstruction, it is possible to use the decoupling model 700 from FIG. 7 in the form of an empirical model. The process of defining the parameters of the empirical model or the material signal function S(i,j) and/or the topography signal function H(i,j) is explained in the subsequent FIG. 13. The method ends at 1250.

The flow diagram 1300 in FIG. 13 presents a method for determining the parameters of a decoupling model 700 in the form of an empirical model. The method begins at 1310. In step 1320, the intensities Iₖ of at least one test structure of a calibrated test sample are recorded by at least two detectors 850, 870 viewing the test structure of the calibrated test sample at least at partly different solid angles. The calibrated test sample is distinguished by the fact that for the calibrated test sample its material contrast information M(i,j) and/or topography contrast information T(i,j) or material contrast distribution and/or topography contrast distribution are/is known.

In step 1330, on the basis of the established material contrast signal function S(i,j) and/or the established topography contrast signal function H(i,j) and the known material contrast information M(i,j) and/or topography contrast information T(i,j) of the calibrated test sample, a reconstructed material contrast signal function S_{R}(i,j) and/or a reconstructed topography contrast signal function H_{R}(i,j) are/is determined or calculated. Step 1340 then involves minimizing the absolute value of the difference between the reconstructed material contrast signal function S_{R}(i,j) and the known material contrast information M(i,j) and/or the reconstructed topography contrast signal function H_{R}(i,j) and the known topography contrast information T(i,j) by varying the parameters of the empirical model, i.e. the reconstructed material contrast signal function S_{R}(i,j) and/or the reconstructed topography contrast signal function H_{R}(i,j).

Decision block 1350 involves checking whether the remaining difference is less than a predefined threshold value. If the remaining difference is greater than a predefined threshold value, the method returns to block 1330 and the current parameters of the reconstructed material contrast signal function S_{R}(i,j) and/or the reconstructed topography contrast signal function H_{R}(i,j) are used to calculate a new reconstructed material contrast signal function S_{R}(i,j) and/or a new topography contrast signal function H_{R}(i,j). The method is then continued with block 1340. If the condition of the decision block 1350 is met, the method 1300 advances to block 1360 and the temporary parameters of the empirical model are stored as the best possible parameters for analyzing the sample 890, 1000, i.e. as a reconstructed material contrast signal function S_{R}(i,j) and/or as a reconstructed topography contrast function H_{R}(i,j). The method ends in block 1370.

In the case of the previously described ascertainment of the parameters of an empirical model on the basis of a pixel-by-pixel determination of the signals Iₖ from two or more detectors 850, 870, it is not possible to take account of non-local effects in the signals. As a result, the topography portions H(i,j) cannot be completely separated from the material contrast portions S(i,j) of the signals Iₖ of the detectors 850, 870. In order to be able to perform this separation more precisely, at the point (i,j) of the sample 890, 1000, the signal of the detectors at the points Iₖ(i-dx,j-dy) must be concomitantly considered. The maximum range (dx,dy) which must be considered here is dependent on the interaction area between the electrons of the primary electron beam and the sample 890, 1000, the topography of the sample 890, 1000 and the electron optics of the detection paths (by way of the acceptance functions Dₖ(E,ϕ)). The sample area to be considered within which there is action of non-local effects typically has linear dimensions in the range of 5 nm to 20 nm.

This means that it is often not sufficient to record only signals Iₖ at individual points of the sample 890, 1090. Rather, a plurality of image signals Iₖ of the detectors 850, 870 must be recorded by use of a scan of the primary electron beam over an area around the individual points (i,j). An image Iₖ is recorded for each of the at least two detectors 850, 870, in the general case k detectors. This relationship also applies to the recording of training data for training a transformation model or an ML model or a DL model.

By performing a convolution operation with one or more suitable convolution kernels wₗ with the recorded image data Iₖ, new signals G_{k,l}(i,j) are generated:

$${G}_{k , l} ( i , j ) = {w}_{l} * {I}_{k} = {\sum }_{d x = - a}^{a} {\sum }_{d y = - b}^{b} {w}_{l} ( dx , dy ) {I}_{k} ( i - d x , j - d y )$$

Known image filters such as, for instance, Sobel filters, Prewitt filters, Laplacian filters, Marr-Hildreth filters, Gaussian filters, or Sharpen filters, can be used as convolution kernels wₗ. The use of further types of filters is likewise possible.

In order that the convolution operation can manifest the corresponding effect, i.e. that of separating non-local effects during the separation of the material contrast and topography contrast portions or material contrast signals and topography contrast signals, it is necessary for the scanning region around the individual points to be chosen to be large enough. For this purpose, the scanning region should be larger than the convolution kernel chosen. Furthermore, for the achievable accuracy it is advantageous for the size of the scanning region to be such that the procedure in the edge region of the scanning region, such as extending, wrap convolution or cropping, for instance, has substantially no influence on the result of the convolution operation. These considerations should be taken into account when choosing the size of the convolution kernel.

The further procedure then takes place as described above. The material signal or the material contrast signal function at the point (i,j) of the sample 890, 1000 is given by:

$$S ( i , j ) = {\sum }_{k} {\sum }_{l} {b}_{k , l} {G}_{k , l} ( i , j ) + {a}_{k} {I}_{k} ( i , j ) + {a}_{0}$$

The absolute value of the difference between the material signal S(i,j) and the material information M(i,j) is minimized by varying the parameters aₖ, b_{k,l}. A reconstructed material contrast signal function S_{R}(i,j) is generated as a result. Data recording within areal regions of the sample 890, 1000 instead of individual points (i,j) makes it possible to minimize the influence of topography effects in a local material signal of the sample 890, 1090. The optimization process explained should be performed for each type of sample, for example each type of mask, and also each operating point of the SEM 800 in FIG. 8.

As described above, it is also possible, of course, to ascertain a topography contrast image, or a height profile or a height profile map of the sample 890, 1000.

The separation of the material contrast and topography contrast portions of a sample image representation or a sample image with the aid of a transformation model is explained below. In the example explained below, the transformation model comprises a machine learning model (ML model), more precisely a deep learning model (DL model). A DL model can be regarded as a network of a plurality of filters whose filter parameters are defined or optimized by the use of deep learning methods.

The data recording takes place, as described above, by the primary electron beam being scanned around individual points (i,j) of the sample 890, 1000. The requirements in respect of the size of the individual scanning regions of the sample 890, 1000 and also the number of scanning points contained therein have already been discussed above.

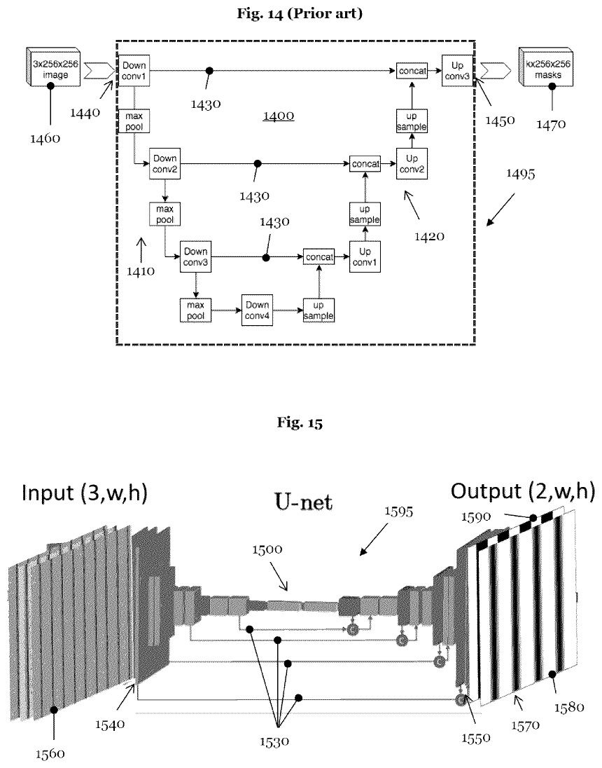

A known architecture that is well suited to denoising and segmentation tasks is the U-Net architecture 1400 indicated in FIG. 14. On the encoder side 1410, the U-Net architecture 1400 comprises alternately blocks that perform down conversion and pooling. On the decoder side 1420, the corresponding blocks perform up conversion and upsampling instead of depooling operations. The outputs of the down conversion blocks of the encoder side 1410, besides being made available to the subsequent pooling block, are additionally made available as input data to the corresponding up conversion blocks on the decoder side 1420. The U-Net architecture 1400 comprises an input layer 1440 on the encoder side 1410 and an output layer 1450 on the decoder side 1420.

In the exemplary U-Net architecture 1400 in the diagram 1495 in FIG. 14, three images with a resolution of 256×256 pixels are provided as input data 1460 via the input layer 1440. For the separation tasks described in this application, the input data 1460 into the U-Net architecture 1400 are the signals Iₖ of the at least two detectors 850 and 870, in the general case k detectors. The scanning regions around the individual points (i,j) of the sample 890, 1000 can comprise scanning regions of 20×20 to 400×400 scanning points. As described above, the accuracy with which non-local effects can be corrected increases with the size of the scanning region and in particular the number of scanning points contained therein. On the other hand, the data recording complexity increases with the square of the length of the scanning region. At the output layer 1450 of the decoder side 1420, a trained U-Net provides the predicted output data 1470, as image data in the example in FIG. 14.

The diagram 1595 in FIG. 15 indicates a U-Net architecture 1500 adapted to the one or more aspects of the present application. In the example in FIG. 15, the signals 1560 recorded by three detectors are provided to the U-Net architecture 1500 via the input layer 1540 thereof. From these data, the trained U-Net architecture 1500 predicts output data 1570 and provides them at the output layer 1550. In the example illustrated in FIG. 15, these output data are an image or an image representation 1590 which represents material contrast of the samples 890, 1000, and an image 1580 having topography contrast. In the example illustrated in FIG. 15, the input data 1560 have a dimension (k, w, h), which are transformed into output data 1570 having a dimension (2, w, h), where k indicates the number of image representations and w and h denote the number of scanning points or pixels in the width and height.

It is also possible to train the U-Net architecture 1500 to provide only one of the two images 1580 or 1590 at its output 1550. Furthermore, the U-Net architecture 1500 can be trained to output at its output 1550, as numerical values, only the contents of material contrast or topography contrast of one or both of the image representations 1580 and 1590. Moreover, the U-Net architecture 1500 can be trained to provide only the changes in material contrast and/or topography contrast at its output layer 1550. Consequently, the U-Net architecture 1500 can be trained to directly output a stop signal for a particle beam-induced repair process of a sample 890, 1000, for instance a photomask, specifically if the predicted material contrast of one of the submitted image representations recorded in a time series changes across a predefined threshold value.

Image sizes (w,h) of 128×128, 64×64 or 32×32 with pixel dimensions in the range of 0.5 nm to 1.5 nm have proved to be advantageous. This results in image sizes of 16 nm×16 nm to 192 nm×192 nm. Thus, with a tenable complexity during image recording non-local effects can be corrected to the greatest possible extent for a decoupling model 700 both in the form of an empirical model and in the form of a transformation model 1500.

As an alternative to the U-Net architectures 1400, 1500 presented in FIGS. 14 and 15 as examples of DL models, ResNet (residual network) architectures can be used for separating material contrast and topography contrast signals in sample image representations. In the case of ResNet architectures, the outputs of a layer are made available as input data not just to the subsequent layer but additionally to one or more layers following the subsequent layer of the encoder and decoder sides.

What is important for the accuracy with which transformation models or ML or DL models 1400, 1500 can predict data is the quality and quantity of the data on the basis of which these models 1400, 1500 can be trained. For training a transformation model or the U-Net architecture 1400, 1500 in FIGS. 14 and 15, images of training samples or test samples are recorded by the at least two detectors 850, 870, or generally by k detectors, which view the test samples at at least partly different solid angles. It is possible, however, that by way of the approach of test samples or calibrated test samples, data that are diverse enough for training the U-Net network 1400, 1500 cannot be recorded and/or that the complexity for generating a sufficient quantity of training data by recording a corresponding number of image representations for training purposes is excessively high. In these cases, a first portion of the training data, as described above, can be generated by measurement, and a second portion by simulation.

As already explained above, a Monte Carlo simulation can determine the interaction between the electrons of a primary beam and the atomic nuclei of a sample 890, 1000 or a test sample on a statistical basis. Simulation tools which can perform Monte Carlo simulations are known, e.g. Nebula (nebula-simulator.github.io). It is thereby possible to generate further images or image representations of test structures of one or more test samples, which supplement the measured image representations of the test samples. The simulation parameters of the tool are adapted such that the simulated images of the test sample(s) can optimally reproduce the experimentally ascertained images.

After the definition of the parameters of the simulation tool for reproducing the test sample(s), in the simulation the test sample(s) can be subjected to random fluctuations and/or systematic changes, so that the spectrum of the simulated test images or of the training data generated by simulation has random and/or systematic changes. In particular, training data generated on the basis of simulations can contain all possible defects of a sample or of a test sample.

The training data generated by simulation have a further advantage. Since the simulated test sample(s) is/are typically based on the design files thereof and/or the specifications of the sample, for instance a photomask, the material contrast and topography contrast portions or material contrast information and topography contrast information for simulated images of the test sample(s) are generally known and the simulated training data can be used directly for training the transformation model, for instance the U-Net architecture 1400, 1500, with compliance with the specification(s). In the case of a photomask, the specifications can comprise for example the sidewall angle and the height of absorbing pattern elements (cf. FIGS. 18 to 22). Compliance with the specifications can be determined, e.g., by scanning the sample(s) or test sample(s) using the measuring tip of an atomic force microscope (AFM).

For experimentally determined test images, the material contrast and topography contrast portions thereof must generally be determined ex situ before these test images can be used as training data for training the U-Net model 1400, 1500.

Once trained, it is possible for relatively small variations of the sample, in the case of photomasks e.g. a slightly different material composition of the absorbing pattern elements, to be trained with the aid of a small number of additional training data; for this purpose, for example, a further layer in the encoder branch 1410, 1510 of the DL model 1400, 1500 can be used, such that the entire network 1400, 1500 need not be retrained. In an alternative embodiment, a hyperparameter which selects a trained model for a specific type of mask from a trained generic photomask model can be provided to the DL model 1400, 1500 at the input layer 1440, 1540 thereof.

Providing an additional parameter at the input layer 1440, 1540 of the DL model 1400, 1500 enables a trained DL model 1400, 1500 to be adapted to a specific repair device in order to provide relatively small variations in the image representation of the detectors 850, 870 and the specific properties thereof to the trained DL model 1400, 1500.

Moreover, generative AI (artificial intelligence) methods can be used to generate SEM images from design files (cf.: Making digital twins using the Deep Learning Kit (DLK), spiedigitallibrary.org), or mask_defect_detection_with_hybrid_deep_learning_network_041205_1.pdf (zeiss.com)). The diagram 1695 in FIG. 16 schematically presents a GAN (generative adversarial network) 1600. GANs typically comprise two artificial neural networks (ANNs), which implement a zero-sum game. A first ANN 1610 is referred to as a generator 1610 and creates candidates. In the example in FIG. 16, from design data 1620 of a photomask, the generator 1610 generates a simulated image 1630 that looks like an image recorded by use of an SEM. The aim of the generator 1610 is to generate simulated SEM images 1630 which cannot be differentiated from images which were generated with the aid of a different kind of simulation, for instance by performing a Monte Carlo simulation 1640. The comparison of the image 1630 generated by the generator 1610 and the simulated image 1640 is illustrated by the box 1660 in FIG. 16.

The second ANN 1650 of the GAN 1600 is called a discriminator 1650 and assesses the candidates. In the example in FIG. 16, these candidates are the simulated images 1640 and the images 1630 generated by the generator 1610. For this purpose, the discriminator 1650 likewise has the images 1640 produced by performing a Monte Carlo simulation, and also images 1670 measured by the SEM 800. The ANN of the discriminator 1650 is trained to differentiate the results supplied by the generator 1610, i.e. the generated SEM images 1630, from genuine measured SEM images 1670. At the output 1680 the GAN 1600 provides the decision as to whether or not it deems the submitted SEM image 1630 generated by the generator 1610 to be genuine in light of the measured SEM images 1670.

This means that, by the use of AI methods, for instance the GAN 1600, training data can be generated directly from design data 1620, and in each case for each test structure of a test sample of a design file 1620 an SEM image 1670 is generated for each detector 850, 870. A precondition for this way of generating training data is, however, that the original training data, i.e. the experimental training data 1670, and/or the simulated training data 1640, contain enough information about the interaction process between the primary electron beam and the atomic nuclei of the sample, such that the GAN 1600 can recognize the underlying structures.

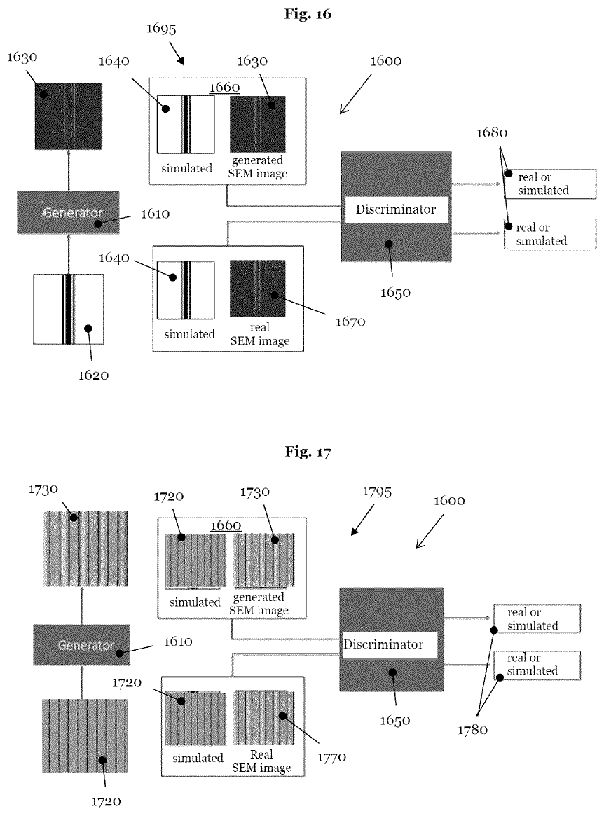

In the case of Monte Carlo simulations, the difficulty often arises that the parameters cannot be defined in such a way that the simulated images 1640 can be brought to congruence perfectly with the images measured by an SEM 800. Better results can be achieved here using a hybrid approach. The diagram 1795 in FIG. 17 schematically shows the GAN 1600 from FIG. 16 again. Images of test structures 1720 which are generated with the aid of Monte Carlo simulations are made available as input data to the generator 1610 of the GAN 1600. The generator 1610 synthesizes therefrom images 1730 that look as though they have been recorded by an SEM 800. The discriminator 1650 of the GAN 1600 compares or assesses the images 1730 generated by the generator 1610 and the measured SEM images 1770 and decides at the output 1780 whether it deems the synthesized image to be genuine. As a result, the simulated images 1720 can be optimized so that the images 1730 synthesized by the generator 1610 can no longer be differentiated from measured images 1770. As explained in the context of FIG. 16, the synthesized images 1730 can then be used as input data for training the GAN 1600. Since the Monte Carlo simulations contain the physics of the interaction process between the primary electron beam and the sample 850, 870, the GAN 1600 can learn something new about the underlying physics.

Test structures of test samples taken as a basis for generating images or image representations which are used for training a DL model 1400, 1500 must contain the largest possible number of different relevant features. If the sample comprises a photomask, examples of relevant features are: various edges of the transition between absorbing pattern elements and the mask substrate, LS (Lines and Spaces) structures having various line widths and pitches, extrusions and intrusions, contact holes, etc. The image representations or images used for training a DL model 1400, 1500, generally a transformation model, need not necessarily comprise entire or large-area SEM images. Rather, image segments are sufficient for this purpose. As explained above, the image segments should comprise linear dimensions of the sample 890, 1000 of the order of 200 nm, such that it is possible to correct non-local effects in the images or image segments with high accuracy.

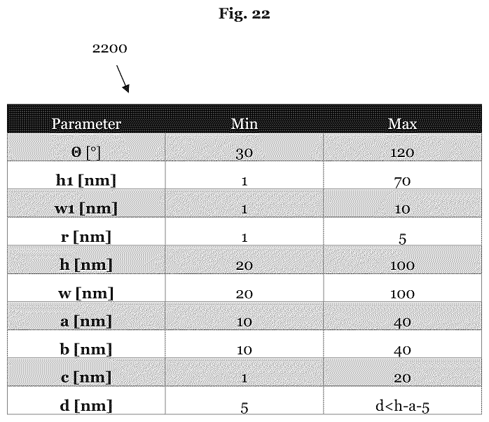

FIGS. 18 to 21 schematically show by way of example some structure elements or features whose image representations can be used for training the ML model 1500. Possible variation ranges of the structure elements from FIGS. 18 to 21 are summarized in the table in FIG. 22.

FIG. 18 illustrates in the upper partial image 1805 and in the lower partial image 1895 in each case a schematic section through a photomask 1800 comprising a mask substrate 1810 composed of a first material M1 and, in the upper partial image 1805, an absorbing and/or phase-shifting pattern element 1820 and, in the lower partial image 1895, an absorbing and/or phase-shifting pattern element 1830 composed of a second material M2. The two pattern elements 1820 and 1830 have a height h and h1, respectively. Furthermore, both pattern elements 1820 and 1830 have a sidewall angle Θ 1840 that is significantly smaller than, for example, a sidewall angle Θ=90° predefined by the specification. The pattern element 1830 of the lower partial image 1895 additionally has an intermediate step 1850 having a width w1 and a height h2. The sidewall angle 1840 of the exemplary mask 1800 has the same numerical value after the intermediate step 1850 as before the intermediate step 1850. However, it is also possible for these two angles not to be equal in magnitude.

FIG. 19 presents an LS (lines and spaces) structure 1900 having a substrate 1910 composed of a first material M1 and, arranged thereon, strips 1920 composed of a second material M2. The two strips 1920 have a width w. Furthermore, the left strip 1920 has an intrusion 1930 of missing material M2 in the form of a trapezium 1930. In the example in FIG. 19, the trapezium has the side lengths a and b and the height c. The right strip 1920 in FIG. 19 has a trapezium-shaped protuberance of excess material M2. In FIG. 19, the trapeziums 1930 and 1940 have the same shape and the same size. Of course, it is possible for the intrusion 1930 and the protuberance 1940 to have different geometric shapes and areas.

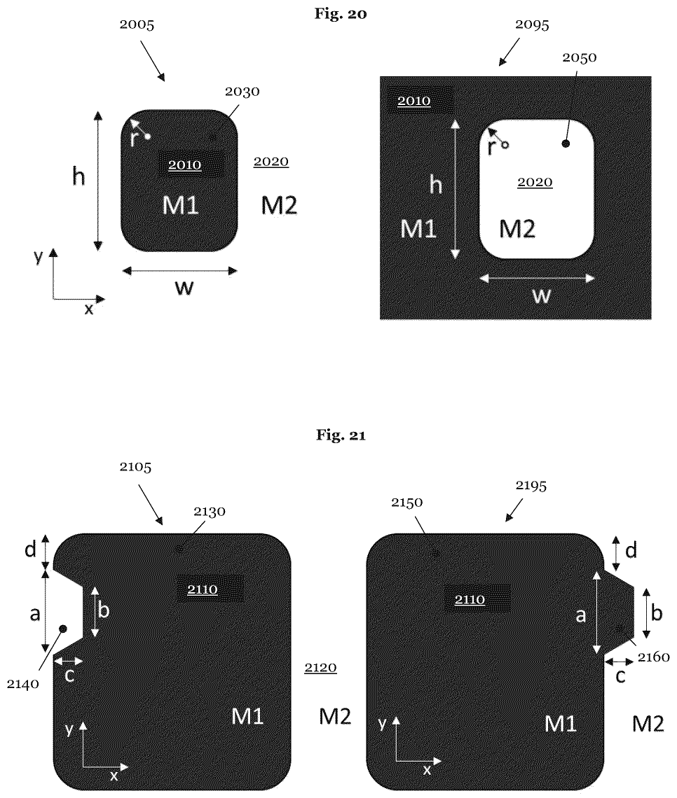

FIG. 20 has test structures for Monte Carlo simulations in the form of a contact hole 2030 in the left partial image 2005 and in the form of a rectangular pattern element 2050 in the right partial image 2095. The rectangular contact hole 2030 can be etched into a pattern element 2050 composed of the material M2 2020 down to the substrate 2010 composed of material M1. The contact hole 2030 has a width w and a height h and a radius r of curvature at the corners of the contact hole 2030. The same dimensions and the same radius of curvature hold true for the pattern element 2050 of the right partial image 2095.

FIG. 21, both in the left partial image 2105 and in the right partial image 2195, presents a test structure in the form of the contact hole 2030 from the left partial image 2005 in FIG. 20. In the left partial image 2105, however, the contact hole 2130 can be etched through the material M2 2120 to the substrate 2110 and has an intrusion 2140 of excess material M2. The intrusion 2140 is once again shaped as a trapezium and begins at a distance d from the upper edge of the contact hole 2130. The contact hole 2150 in the right partial image 2195 can again be etched through the material M2 2120 to the substrate 2110 and has a bulge 2160 in the form of a defined “defect” 2160 of missing material M2. This defect has the same dimensions as the defect 2140 in the left partial image 2105 in the form of an intrusion 2140 and is arranged mirror-symmetrically with respect to the defined intrusion 2140.

The table 2200 in FIG. 22 indicates the variation ranges of the parameters from FIGS. 18 to 21 within which defects 1930, 1940, 2140, 2160 can be systematically produced, such that the training data generated on the basis of these structure elements 1820, 1830, 1930, 1940, 2130, 2160 are diverse enough. The generated structure elements including their variations are decomposed into polygons and used as input or input data for Monte Carlo simulations.

A second exemplary embodiment for determining the topography contrast contribution and the material contrast contribution of two image representations recorded simultaneously at different solid angles is explained below. The second exemplary embodiment by way of example uses a machine learning model 1500 as a decoupling model 700.

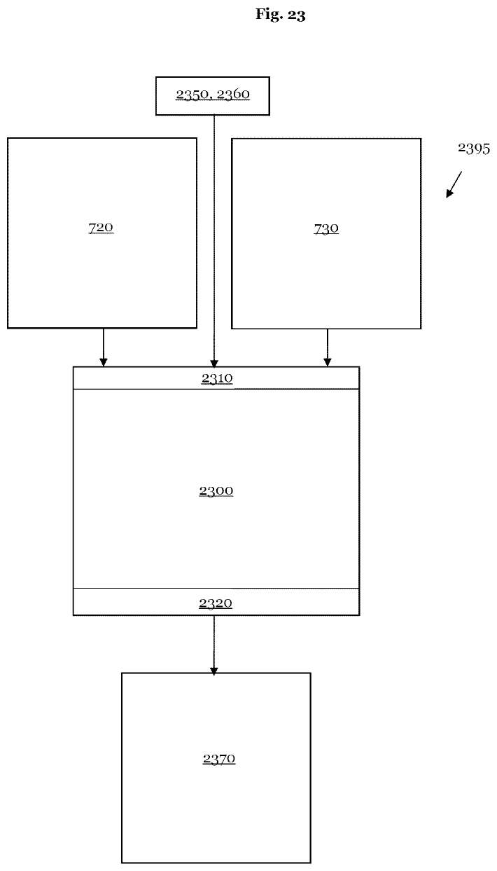

The diagram 2395 in FIG. 23 schematically illustrates the implementation of a trained ML model 2300, which converts a first measured image representation 720 and a second measured image representation 730 into a transformed image representation 2370 having a predefined topography contrast and material contrast ratio. The ML model 2300 can comprise a deep learning model, for example the U-Net architecture 1500.

In accordance with one of the aspects of the present application, the transformed image representation 2370 is based on an intensity distribution caused exclusively by the material composition of the sample 890, 1000, in the present example the photomask 890, 1000. Besides the image representations 720, 730, in addition at least one parameter 2350 and/or at least one hyperparameter 2360 are/is provided to the trained machine learning model 2300 via the input layer 2310 thereof. Additional parameters 2350 and hyperparameters 2360 are discussed in the third part of this description. By use of a hyperparameter 2360, for example a sample 890, 1000 present in the form of a photomask 890, 1000 can be classified as a binary mask.

The image representations 720, 730 are two-dimensional pixel matrices in a greyscale value representation. The pixel matrices can currently have sizes in the range of 2⁰·2⁰ to 2¹⁶·2¹⁶. A pixel can be encoded with a depth of 2⁴ to 2¹⁰ bits. The size of the matrices and the pixel depth can be the same for both image representations 720, 730. However, the ML model 2300 may also have been trained to process image representations with different sizes of matrices and/or pixel depths. Furthermore, an ML model 2300 can be trained to process three or more image representations 720, 730 submitted to the input layer 2310 to form a single transformed image representation 2370 (not illustrated in FIG. 23).

The trained ML model 2300 provides the transformed image representation 2370 at its output layer 2320. The transformed image representation 2370 can have the same matrix size and the same pixel depth as one of the two image representations 720, 730 submitted at the input 2310. However, it is also possible for the transformed image representation 2370 to have a different matrix size and/or pixel depth compared with one of the two image representations 720, 730.

The ML model 2300 can comprise one of the models described in the summary section of this description. It is advantageous to select, from a multiplicity of generic ML models available, a model adapted to the problem to be solved. Furthermore, it is advantageous to adapt a selected generic ML model 2300 to the problem to be solved and to the required prediction accuracy. U-Net architectures 1500 and/or ResNet architectures have proved to be advantageous for the problem to be solved. The ML model 2300 can be adapted for example by means of an adaptation of the complexity of the kernel function of an ML model 2300. In the case of an ML model 2300 having an encoder-decoder architecture, this can be implemented for example by means of a corresponding choice of the number of layers in the ML or DL model 2300. For an ML model 2300 realized for example in the form of a mixture form described above, for instance the number of leaves in an RDT or the number of trees in an RDF can be adapted to the problem to be solved.

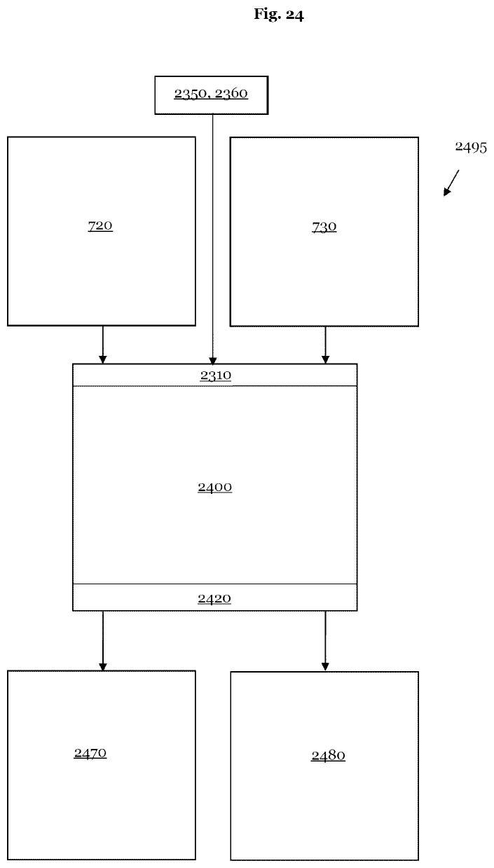

The diagram 2495 in FIG. 24 presents an ML model 2400 representing a modification of the ML model 2300 from FIG. 23. Unlike the ML model 2300, the ML model 2400 has been trained to generate two transformed image representations 2470, 2480 from the two image representations 720, 730 submitted at the input 2310. The two transformed image representations 2470, 2480 can have the same matrix sizes and pixel depths or these variables of the two transformed image representations 2470, 2480 can be different. The two transformed image representations 2470, 2480 can represent different ratios of topography contrast and material contrast of the image representations 720, 730. In particular, the ML model 2400 can be trained for example to the effect that the transformed image representation 2470 represents only topography contrast and the transformed image representation 2480 represents exclusively material contrast. A stop signal for a local chemical sample repair process can be derived from the transformed image representation 2480 with high accuracy.

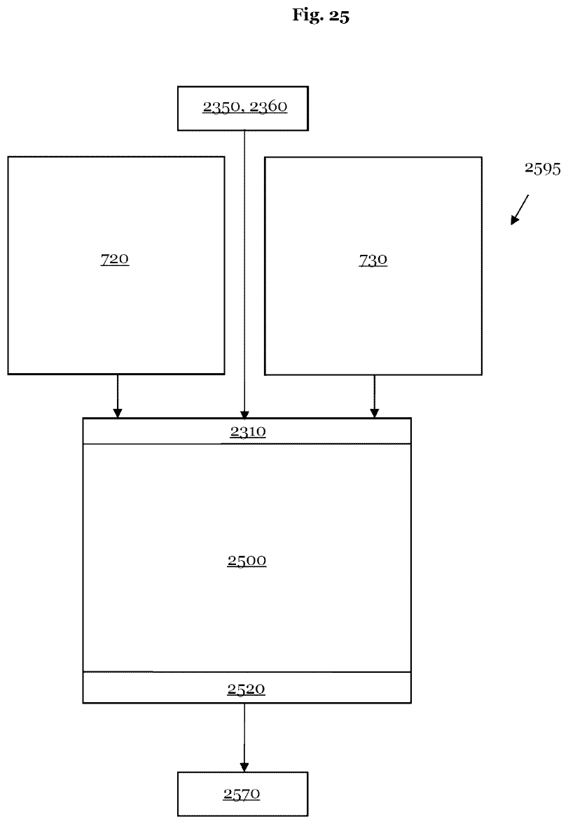

The diagram 2595 in FIG. 25 illustrates a further possible variation of the ML model 2300. The trained machine learning model 2500 has been trained to provide at its output layer 2520 the topography contrast contribution and the material contrast contribution 2570 of one or both of the image representations 720, 730. It is also possible, of course, to train the ML model 2500 to make available only the material contrast portion of the image representation 730 at the output layer 2520.

Furthermore, the ML model 2500 can be trained directly to generate a stop signal for a local chemical repair process. For this purpose, the ML model 2500 is trained to recognize a change in the material contrast contribution of a first set of image representations 720, 730 and a second set of image representations 720, 730, which was recorded at a later point in time. If this change exceeds a predefined threshold value, the trained ML model 2500 makes a corresponding signal available at its output layer 2520. As long as the temporal profile of a material contrast change of a set of image representations 720, 730 remains below the predefined threshold value, by contrast, no data are output by the correspondingly trained ML model 2500.

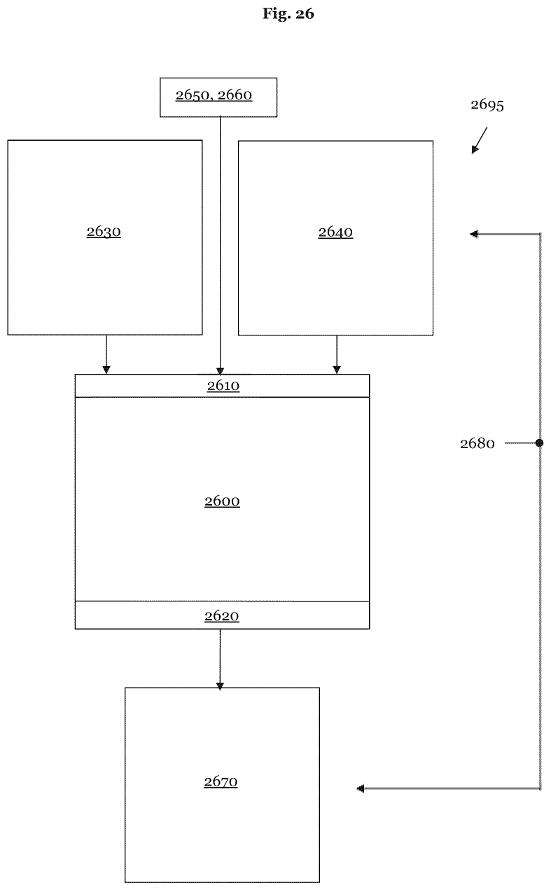

Before one of the machine learning models 1500, 2300, 2400, 2500 can be used to fulfil the intended task, these models need to be trained for the envisaged purpose of use. The diagram 2695 in FIG. 26 schematically shows the training of a machine learning model 2300, 2400, 2500 or of an ML model 2300, 2400, 2500. Before the ML model 2300 can predict a transformed image representation 2370 from the submitted image representations 720, 730, the ML model 2300 must be trained with an extensive data set or training data set for this task. This also applies, of course, to the ML models 2400 and 2500.

In order to generate the training data, long measurement series of the same type comprising image representation tuples from samples used for training are carried out by a measuring device, for instance the SEM 800. In the example discussed, the sample 890, 1000 is a segment from a photomask 300. Alternative samples may be wafers, templates for nanoimprint lithography, MEMS, NEMS or PICs. In the present application example, the image representation tuples comprise pairs of two image representations recorded from different representatives of a sample class at at least partly different solid angles. In the example under discussion, N different binary photomasks having different absorber patterns, which additionally cover the entire spectrum of known defects, are measured in the same way by a measuring device, for instance the SEM 800, with a detector configuration with two detectors 850, 870, where N must be chosen with a magnitude such that the relevant characterizing parameters of the image representation tuples, namely the topography contrast contribution and the material contrast contribution of the image representation tuples, change significantly during the process of measuring the training data set. Furthermore, it is possible to vary the measurement environment and thus the characterizing parameters systematically during the recording of training data, in order to generate as representative a database as possible for training purposes. For this purpose, the sample set, i.e. the set of binary masks, can include, besides fault-free binary masks, defective binary masks, also repaired binary masks 300, 890, 1000 and in particular masks 300, 890, 1000 in every stage of a repair process.

Under a second numerical value of a hyperparameter 2660, a generic model for a second type of mask can be trained, for instance for phase-shifting masks. This means, for example, the hyperparameter 2660 may determine a type of a photomask (e.g. binary mask, phase-shifting mask, transmitting mask, reflective mask, multiple exposure mask).

The training data set comprises the characterizing image representation tuples 2630 and 2640 used for training together with at least one additional parameter 2650 which characterizes the measuring device for measuring the image representation tuples 2630, 2640, and/or at least one hyperparameter 2660. For example, the additional parameter 2650 may determine the type of measuring device used for measuring the image representation tuples 2630, 2640. It may determine the type(s) of detectors, their size, and their arrangement within the measuring device. The additional parameter may depend on the solid angle range within which the detectors 850, 870 can detect secondary particles 860, 880. Furthermore, the one or more additional parameters 2650 may comprise the exposure settings and/or aberrations of the measuring device. The training data are provided to the training ML model 2600 at an input layer 2610. The hyperparameter 2660 may indicate a classification of the characterizing image representation tuples 2630 and 2640 used for training as indicated above. For example, the hyperparameter 2660 may indicate characterizing image representation tuples 2630 and 2640 characterizing or classifying a specific type of photomask as indicated above.

Typically, the training phase may comprise several stages. For example, if the generic ML model is a generic regenerative ML model, the training generic regenerative ML model may reproduce the image representations 2630 and/or 2640 in a pre-training phase. In the pre-training phase only a portion of the encoder layers may be active. The pre-training phase may be used for determining or fixing a portion of the internal parameters of the training ML model 2600.

During the training phase, the training or learning ML model 2600 generates a transformed image representation 2670 from the training characterizing pairs of image representations 2630 and 2640 and the associated additional parameter 2650 and/or the hyperparameter 2660. In the following, as an example, the training of the specific ML 2300 of FIG. 23 is briefly explained. The predicted transformed image representation 2670 is compared with a difference of the image representations 2630 and 2640 of the assigned image representation tuple 2630, 2640. The difference of the image representations 2630 and 2640 may indicate the difference in the material contrast and/or the topography contrast between the two image representations 2630 and 2640. During the training phase the training or learning model 2600 minimizes the difference between the difference of the image representations 2630 and 2640 on the one hand and the image representation 2670 in order to adapt or fix the internal parameters of the ML model 2600. This is illustrated by the double-headed arrow 2680 in FIG. 26. The training ML model 2600 provides the predicted transformed image representation 2670 at its output layer 2620. In the example discussed in the context of FIG. 23, the predicted transformed image representation 2670 may represent the transformed image representation having a predefined topography contrast and/or material contrast ratio. It is also possible, of course, to train the ML model 2600 to provide two transformed image representations at its output layer 2620, a first representing material contrast and a second representing topography contrast of the sample (not depicted in FIG. 26). When the ML model 2600 is trained in this way, the trained ML model 2600 represents the ML model 2400 of FIG. 24. Further, it is also possible to train the ML model 2600 to provide at its output layer 2620 in order to generate the ML model 2500.

Depending on the ML model 2300, 2400, 2500 chosen, there are various methods for adapting the parameters of the ML model 2300, 2400, 2500 in the training phase. By way of example, the iterative technique “stochastic gradient descent” has become established for a DNN (deep neural network), which typically has a multiplicity of parameters. In this case, the training data are repeatedly “submitted” to the learning ML model 2600, i.e., the latter calculates a prediction for the transformed image representation 2670 from the characterizing image representation tuple 2630, 2640 used for training with its current parameter set. The comparison discussed above is carried out afterwards. If deviations arise between the transformed image representation 2670 and the actual value of the topography contrast and/or the material contrast associated with the chosen image representation 2630 or 2640, in which the differences or deviations in the actual value of the topography contrast and/or the material contrast of the image representations 2630 and 2640 on the one hand and the image representation 2670 on the other hand show or reveal a parameter mismatch of the training ML model 2600, the parameters of the learning ML model 2600 are adapted. The training phase ends once a local optimum is reached, i.e., the deviations of the predicted topography contrast and/or the predicted material contrast and the actual topography contrast and/or material contrast of the image representation 2630 or 2640 no longer vary, or else a predefined time budget for the training cycle of the learning or training ML model 2600 has been used up.

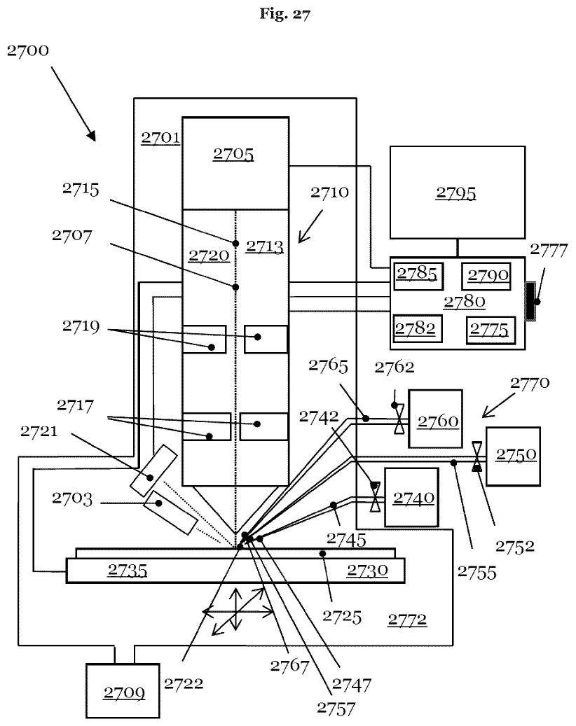

The characterizing image representation tuples 2630, 2640 used for training can originate from a particle beam-based measuring device, for example the SEM 800 from FIG. 8 and/or the repair device 2700 to be discussed in the context of FIG. 27. However, it is also possible to use the method described in this application for any measuring devices that generally use a particle beam for imaging an element of a photolithography process. In particular, the method explained here can be used for a scanning electron microscope and/or a measuring device that uses an ion beam for imaging a photomask or a wafer.

FIG. 27 shows a schematic section through some important components of a device 2700 designed to simultaneously record two image representations of a sample with two detectors, the solid angles of which overlap partly at most. In the exemplary device 2700 in FIG. 27, the two image representations recorded simultaneously by two detectors differ in their polar angle portions. Furthermore, the device 2700 can apply a decoupling model 700 in order to determine a topography contrast portion and/or a material contrast portion of at least one of the at least two image representations 720, 730. Moreover, the device 2700 is configured to train a transformation model and/or a machine learning model 1500, 2300, 2400, 2500—as examples of a decoupling model 700 in the form of a transformation model. In addition, the device 2700 is designed to repair a sample defect by performing a particle beam-induced local chemical process. The exemplary device 2700 in FIG. 27 comprises a modified scanning particle microscope 2710 in the form of a scanning electron microscope (SEM) 2710 in combination with a gas providing system 2770.

The device 2700 comprises a particle beam source 2705 in the form of an electron beam source 2705, which generates an electron beam 2715 as particle beam 2715. An electron beam 2715 has the advantage—compared with an ion beam—that the electrons 2707 incident on the sample 2725 or the lithographic mask 300, 890, 1000 substantially cannot damage the sample 2725 or the mask 300, 890, 1000. However, it is also possible to use (not illustrated in FIG. 27) in the device 2700 an ion beam, an atomic beam, a molecular beam or a high-energy photon beam, for example electrons from the extreme ultraviolet (EUV) wavelength range, for the purpose of processing the sample 2725.

The scanning particle microscope 2710 is composed of an electron beam source 2705 and an electron-optical column 2720, in which is arranged the beam optical unit 2713 for instance in the form of an electron optical unit of the SEM 2710. In the SEM 2710 in FIG. 27, the electron beam source 2705 generates an electron beam 2715, which is directed as a focused electron beam 2715 onto the sample 2725, which can comprise the photolithographic mask 300, 890, 1000, for example, at the location 2722 by the imaging elements arranged in the column 2720, said imaging elements not being illustrated in FIG. 27. The beam optical unit 2713 thus forms the imaging system 2713 of the electron beam source 2705 of the SEM 2710.

The imaging elements of the column 2720 of the SEM 2710 can furthermore scan the electron beam 2715 over the sample 2725. The sample 2725 can be examined, i.e. analyzed and processed, with the aid of the electron beam 2715 of the SEM 2710. A stop or a stop system comprising multiple stops (not illustrated in FIG. 27) can be installed in the electron-optical column 2720 of the SEM 2710, preferably downstream of a condenser lens of the SEM 2710. The stop or the stop system can be set by a setting unit 2790 of the computer system 2780 of the device 2700.

The secondary particles, namely the backscattered electrons (BSE) and the secondary electrons (SE), generated by the electron beam 2715 as the primary particle or electron beam 2715 in the interaction region of the sample 2725 are registered by a combination of two detectors 2717 and 2719. In the exemplary configuration in FIG. 27, the two detectors 2717 and 2719 are referred to as “in lens detectors”. Since the detector 2717 is mounted in close proximity to the sample 2725 in a ring-shaped manner around the primary particle beam 2715, it collects secondary particles over a large solid angle range. The latter is symmetrical about the polar angle which is related to the beam axis of the electron beam 2715. Moreover, the detector 2717 only has an opening with a small diameter for the passage of the primary particle beam 2715 and therefore also detects secondary particles, in particular BSE, which are reflected from the sample 2725 at a small angle (polar angle) relative to the beam axis of the primary particle beam 2715.

The detector 2719 installed above the detector 2717 in the column 2720 predominantly images BSE which are emitted by the sample 2725 at a very small angle relative to the axis of the primary particle beam 2715 or the electron beam 2715, i.e. at a very small polar angle. The solid angles at which the two detectors 2717 and 2719 view the sample 2725 are at least partly different since the detector 2717 partly shades the detector 2719. In the exemplary detector configuration presented in FIG. 27, the solid angle portions of the two detectors 2717 and 2719 differ in their polar angles. The two detectors 2717 and 2719 can be installed in different embodiments and at different positions in the column 2720. The two detectors 2717 and 2719 convert the SE generated by the electron beam 2715 at the measurement point 2722 and/or the BSE backscattered from the sample 2725 into an electrical measurement signal and forward the latter to an evaluation unit 2785 of a computer system 2780 of the device 2700. The detector 2719 can contain a filter or a filter system in order to discriminate the SE and/or BSE in terms of energy (not depicted in FIG. 27). The detectors 2717 and 2719 are controlled by a setting unit 2790 of the device 2700.

Furthermore, the exemplary device 2700 can include a third detector 2721. The third detector 2721 can be designed to detect electromagnetic radiation, in particular in the x-ray range. As a result, the detector 2721 makes it possible to analyze a material composition 450, 460 of the radiation generated by the sample 2725 during an examination of the sample 2725. The detector 2721 is likewise controlled by the setting unit 2790.

Furthermore, the device 2700 can comprise a fourth detector (not illustrated in FIG. 27). The fourth detector is often embodied in the form of an Everhart-Thornley detector and typically arranged outside the column 2720. It is generally used to detect SE.

The device 2700 comprises a flood gun 2703. This is able to provide ions with low kinetic energy in the region of the sample 2725. The flood gun 2703 can furthermore be configured to provide electrons 2707 with settable landing energy E₀ in that region of the sample 2725 which is to be processed and/or to be analyzed. The ions with low kinetic energy and/or the electrons 2707 with settable landing energy E₀ are able to compensate for an electrostatic charge of the sample 2725.

Moreover, the device 2700 can comprise a mesh or a screening grid at the output of the column 2720 of the modified SEM 2710 (not shown in FIG. 27). By applying an electrical voltage between the mesh or the screening grid and a metal tube (liner tube) mounted in the region of the objective lens of the column 2720, which metal tube is likewise not shown in FIG. 27, it is possible to generate a settable potential for the electrons 2707 of the electron beam 2715, such that their landing energy E₀ can be changed by a desired value. In addition, the mesh can likewise be used to compensate for an electrostatic charge of a sample 2725. It is furthermore possible to earth the screening grid mesh.

In addition to the electron beam source 2705, the device 2700 can comprise a second radiation source (not shown in FIG. 27). The second radiation source can be a second electron beam source or a radiation source for a different type of particles, for instance for ions, atoms, molecules or high-energy photons.

The sample 2725 is arranged on a sample stage 2730 or a sample holder 2730 for examination. A sample stage 2730 is also known as a “stage” in the specialist field. As symbolized by the arrows in FIG. 27, the sample stage 2730 can be moved in three spatial directions relative to the column 2720 of the SEM 2710, for example by way of micro-manipulators that are not illustrated in FIG. 27.

Besides the translational movements, the sample stage 2730 can be rotated at least about an axis oriented parallel to the beam direction of the particle beam source 2705. It is furthermore possible for the sample stage 2730 to be embodied such that it is rotatable about one or two further axes, this axis or these axes being arranged in the plane of the sample stage 2730. The two or three axes of rotation preferably form a rectangular coordinate system. As can be gathered from FIG. 27, the rotation of the sample stage 2730 about an axis of rotation that is arranged in the plane of the sample stage 2730 is often possible only to a limited extent on account of the small distance between the end of the column and the sample 2725.

The sample 2725 to be examined can be any microstructured component or component part requiring analysis, i.e. sample imaging, and possibly subsequent processing, for example the repair of a local defect of a lithographic mask 300, 890, 1000. In this regard, the sample 2725 can comprise for example a transmissive or a reflective photomask 300, 890, 1000 and/or a template for nanoimprint technology or nanoimprint lithography. A transmissive and the reflective photomask 300, 890, 1000 can comprise all types of photomasks, such as for instance binary masks, phase-shifting masks, OMOG masks, or masks for a double or multiple exposure.

The device 2700 in FIG. 27 can furthermore comprise one or more scanning probe microscopes, for example in the form of an atomic force microscope (AFM) (not shown in FIG. 27), which can be used to analyze and/or process the sample 2725.

The scanning electron microscope 2710 illustrated by way of example in FIG. 27 is operated in a vacuum chamber 2701. In order to generate and maintain a reduced pressure required in the vacuum chamber 2701, the SEM 2710 in FIG. 27 comprises a pump system 2709.

Furthermore, the device 2700 includes a computer system 2780. Said computer system comprises a setting unit 2790 configured to set the landing energy E₀ of the electrons 2707 of the electron beam 2715 to a predefined value. For this purpose, the setting unit 2790 can set the acceleration voltage of the electrons 2707 of the electron beam 2715 and also their deceleration voltage. Furthermore, the setting unit 2790 can set the potential of the energy filter of the detector 2719.

Moreover, the computer system 2780 can have an interface 2777 via which the computer system 2780 receives information about the sample 2725, for instance its material composition and/or its surface contour. In addition, the computer system 2780 can obtain information about a defect of the sample 2725. In addition, the computer system 2780 can obtain image representations 720, 730 of the sample 2725 via the interface 2777 and/or transmit image representations 720, 730 of the sample 2725 via the interface 2777.

The computer system 2780 can also comprise a scanning unit 2782, which scans the electron beam 2715 over the sample 2725. The setting unit 2790 can furthermore be configured to set the various parameters of the modified scanning particle microscope 2710 of the device 2700. The setting unit 2790 can furthermore control the micro-manipulators and rotation of the sample stage 2730. The scanning unit 2782 and the setting unit 2790 of the computer system 2780 may be realized in software which can be executed by the processor 2775 of the computer system 2780. Further, the scanning unit 2782 and/or the setting unit 2790 may be realized in form of specific hardware components. For example, these components may be realized in form of a field-programmable gate array (FPGA), programmable logic circuit (PLC) or an application specific integrated circuit (ASIC).

Moreover, the evaluation unit 2785 of the computer system 2780 can analyze the measurement signals from the detectors 2717 and 2719 and generate therefrom an image or an image representation 720, 730 of the sample 2725 that is able to be displayed by a display 2795. In particular, the evaluation unit 2785 can be designed to determine the position and a contour of a defect of missing material and/or a defect of excess material of a sample 2725, for instance of the lithographic mask 300, 890, 1000, from the measurement data of the detectors 2717 and 2719.

Furthermore, the computer system 2780 can be configured to apply a decoupling model 700 to the image representations 720, 730 generated by the detectors 2717 and 2719, in order to determine the topography contrast and material contrast contributions of said image representations. For this purpose, the computer system 2780 can contain one or more algorithms that make it possible to ascertain the parameters of an empirical model from two image representations 720, 730 of the sample 2725. The algorithms of the computer system 2780 can be implemented using hardware, software or a combination thereof. In particular, the one or more algorithms can be realized in the form of an ASIC (application-specific integrated circuit), a PLD (programmable logic device) and/or an FPGA (field programmable gate array).

The computer system 2780 and/or the evaluation unit 2785 can include a memory (not illustrated in FIG. 27), preferably a non-volatile memory, which stores a transformation model and/or a machine learning model 1500, 2300, 2400, 2500 in generic form and/or in trained form. Furthermore, the non-volatile memory of the computer system 2780 can store a training data set for a transformation model and/or an ML model 2300, 2400, 2500. The evaluation unit 2785 can be designed to determine the topography contrast portion and/or the material contrast portion of the image representations 720, 730 of the sample 2725 from the image representations 720, 730. It may be implemented as a hardware component, for example a processor (not shown in FIG. 27) or may be realized in form of an integrated circuit specifically designed for evaluating topography and material contrast. For example, the evaluation unit 2785 may be realized as an application specific integrated circuit (ASIC). Alternatively, the evaluation unit 2785 may be software program which may be executed by a processor 2775 of the computer system 2780. The processor 2775 of the computer system 2780 may be the general purpose processor of the computer system 2780. It is also possible that the processor 2775 of the computer system 2780 comprises a co-processor dedicated to the evaluation task of the evaluation unit 2785. The specific hardware component of the evaluation unit 2785 and/or the processor 2775 of the computer system 2780 may execute instructions to apply the empirical model and/or the transformation model. In particular, the hardware component of the evaluation unit 2785 and/or the processor 2775 of the computer system 2780 may execute instructions to apply the ML model 1500, 2300, 2400, and 2500.

Further, the training of the ML model 2600 may be performed by the processor 2775 of the computer system 2780. Alternatively, it may be performed by a processor of the evaluation unit 2785. It is also possible to perform the training of the generic ML model 2600 on a remote computer system (not shown in FIG. 27).

Furthermore, the computer system 2780 can comprise an interface 2777 for exchanging data with the Internet, an intranet and/or some other device. The interface 2777 can comprise a wireless or wired interface. The evaluation unit 2785 can provide the setting unit 2790 with data which enable the setting unit 2790 to stop a local chemical repair process of the sample 2725.

The evaluation unit 2785 and/or the setting unit 2790 can be integrated into the computer system 2780, as indicated in FIG. 27. However, it is also possible to embody the evaluation unit 2785 and/or the setting unit 2790 as stand-alone unit(s) within or outside the device 2700. In particular, the evaluation unit 2785 and/or the setting unit 2790 can be designed to perform some of their tasks by use of a dedicated hardware implementation.

Furthermore, the computer system 2780 can be integrated into the device 2700 or can be designed as a stand-alone device (not shown in FIG. 27). The computer system 2780 can be embodied using hardware, software, firmware or a combination.

The gas providing system 2770 realized by the device 2700 is discussed below. As already explained above, the sample 2725 is arranged on a sample stage 2730. The imaging elements 2713 of the column 2720 of the SEM 2710 can focus the electron beam 2715 and scan it over the sample 2725. The electron beam 2715 of the SEM 2710 can be used to induce a particle beam-induced deposition process (EBID, electron beam-induced deposition) and/or a particle beam-induced etching process (EBIE, electron beam-induced etching). In order to perform these processes, the exemplary device 2700 in FIG. 27 comprises three different supply containers 2740, 2750 and 2760 for storing various precursor gases.

The first supply container 2740 stores a precursor gas, for example a metal carbonyl, such as chromium hexacarbonyl (Cr(CO)₆) or molybdenum hexacarbonyl (Mo(CO)₆). With the aid of the precursor gas stored in the first supply container 2740, material missing from the lithographic mask 300, 890, 1000 can be deposited thereon in a local chemical deposition reaction, for example. Furthermore, a protective layer or a sacrificial layer can be deposited on the mask 300, 890, 1000 by way of the precursor gas stored in the first supply container 2740. In addition, drift markers can be deposited on the mask 300, 890, 1000 or the sacrificial layer by way of the precursor gas stored in the first supply container 2740.

The electron beam 2715 of the SEM 2710 acts as an energy supplier for splitting the precursor gas, which is stored in the first supply container 2740, at the location where material is intended to be deposited on the sample 2725. This means that the combined provision of an electron beam 2715 and a precursor gas leads to an EBID process being carried out for local deposition of missing material, for example material missing from the mask 300, 890, 1000.

An electron beam 2715 can be focused to a spot diameter in the range of a few nanometers. The region of interaction or the scattering cone in which an electron beam 2715 generates SE depends firstly on the energy of the electron beam 2715 and secondly on the material composition on which the electron beam 2715 is incident. The diameters of regions of interaction attain values in the low single-digit nanometer range. The diameter of a scattering cone of an electron beam 2715 thus limits the achievable resolution limit when carrying out a local particle beam-induced reaction. This resolution limit is at present is in the single-digit nanometer range.

In the device 2700 illustrated in FIG. 27, the second supply container 2750 stores an etching gas that allows a local electron beam-induced etching (EBIE) process to be carried out. With the aid of an electron beam-induced etching process, excess material can be removed from the sample 2725, for instance the excess material of the intrusion 1940 of the right strip 1920 and/or of the contact hole 2130. By way of example, an etching gas can comprise xenon difluoride (XeF₂), a halogen or nitrosyl chloride (NOCl).

An additive or additional gas can be stored in the third supply container 2760, said gas, where necessary, being able to be added to the etching gas kept available in the second supply container 2750 or to the precursor gas stored in the first supply container 2740. Alternatively, the third supply container 2760 can store a second precursor gas or a second etching gas.

In the device 2700 illustrated in FIG. 27, each of the supply containers 2740, 2750 and 2760 of the gas providing system 2770 has its own control valve 2742, 2752 and 2762 in order to supervise or control the amount of the corresponding gas that is provided per unit time, that is to say the gas volumetric flow at the location 2722 where the electron beam 2715 is incident on the sample 2725. The control valves 2742, 2752 and 2762 can be controlled or supervised by the setting unit 2790 of the computer system 2780. By this means, it is possible to set the partial pressure conditions of the gas or gases provided at the processing location for carrying out an EBID and/or EBIE process in a wide range.

Furthermore, in the exemplary device 2700 in FIG. 27, each supply container 2740, 2750 and 2760 has its own gas feed line system 2745, 2755 and 2765, which ends with a nozzle 2747, 2757 and 2767 in the vicinity of the point 2722 of incidence of the electron beam 2715 on the sample 2725.

The supply containers 2740, 2750 and 2760 can have their own temperature setting element and/or control element, which allows both cooling and heating of the corresponding supply containers 2740, 2750 and 2760. This makes it possible to store and in particular provide the precursor gas at the respectively optimum temperature (not shown in FIG. 27). The setting unit 2790 can control the temperature setting elements and the temperature control elements of the supply containers 2740, 2750, 2760. During the EBID and the EBIE processing processes, the temperature setting elements of the supply containers 2740, 2750 and 2760 can furthermore be used to set the vapour pressure of the precursor gases stored therein by way of the selection of an appropriate temperature.

The device 2700 can comprise more than one supply container 2740 in order to store two or more precursor gases. The device 2700 can furthermore comprise more than one supply container 2750 in order to store two or more etching gases (not shown in FIG. 27).

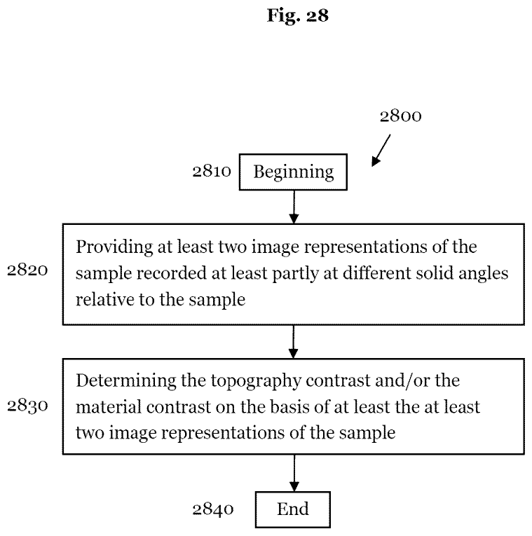

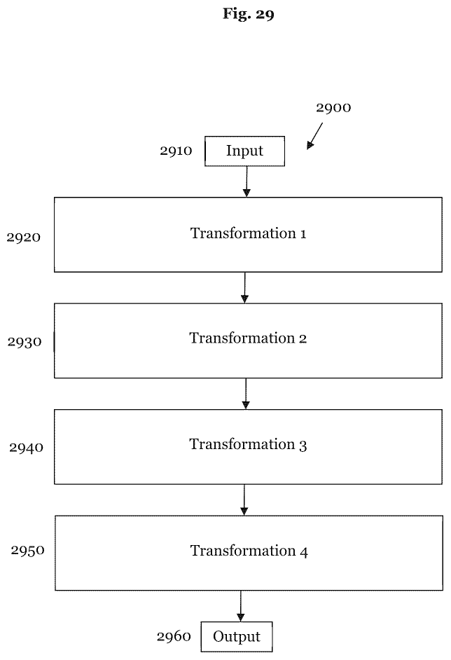

Finally, the flow diagram 2800 in FIG. 28 represents important steps of a method for determining a topography contrast portion and/or a material contrast portion of an image representation 720, 730 of a sample 890, 1000, 2725. The method begins in step 2810.

Step 2820 involves providing at least two image representations 720, 730 of the sample 890, 1000, 2725 recorded at least partly at different solid angles relative to the sample. The providing can comprise loading the at least two image representations 720, 730 from a non-volatile memory, transmission via a network and/or recording of the at least two image representations 720, 730 for example by use of the detectors 2717 and 2719.

Step 2830 involves determining the topography contrast and/or the material contrast of the sample at least partly on the basis of the at least two image representations 720, 730 of the sample 890, 1000, 2725. A decoupling model 700 can be used for this purpose. A decoupling model 700 can comprise a parametrized empirical model and/or a trained transformation model, for instance a deep learning model 1500, 2300, 2400, 2500, which is applied to the at least two image representations 720, 730 of the sample 890, 1000, 2725. A computer system 2780 configured for this purpose of use, for example by way of a specific graphics processor unit and/or one of the hardware components specified above, can implement the decoupling model 700 by application to the at least two image representations 720 and 730.

The method ends in step 2840.

Finally, FIG. 29 schematically illustrates an example of a transformation model 2900 having four transformation blocks 2920, 2930, 2940, and 2950. Input 2910 is entered into the first transformation block 2920 and the transformation model 2900 provides its result at the output 2960. The transformation model 2900 does not necessarily have an encoder, a feature projection, and a decoder. Rather, the exemplary transformation model 2900 of FIG. 29 has four transformation blocks 2920, 2930, 2940, and 2950 each containing at least one learnable function which transforms or translates in a sequential arrangement input into output which is input for the subsequent transformation block. The transformation model 2900 does not claim to transform a suitable and therefore transformable representation of the input 2910 in an intermediate step into a feature projection. The input 2910 may be the input data of the ML models 1500, 2300, 2400, 2500. The output 2960 provided at the output of the fourth transformation block 2950 may be the image representations 2370, 2370, 2480 of the ML models 1500, 2300, 2400 or the output data 2570 of the ML model 2500. Similar to the ML models 1500, 2300, 2400, and 2500, the input 2910 may contain one or more additional parameters 2350 or one or more hyperparameters 2360 characterizing a photolithographic mask 2725 and/or a measuring system 800, 2700.

Although the present invention is defined in the attached claims, it should be understood that the present invention can also be described in accordance with the following examples:

Example 1: Method (2800) for determining a topography contrast (585) and/or a material contrast (550, 560) of a sample (300, 890, 1000), comprising:
a. providing (2820) at least two image representations (720, 730) of the sample (300, 890, 1000) recorded at least partly at different solid angles relative to the sample (300, 890, 1000); and
b. determining (2830) the topography contrast (585) and/or the material contrast (550, 560) of the sample (300, 890, 1000) at least partly on the basis of the at least two image representations (720, 730) of the sample (300, 890, 1000).

Example 2: Method (2800) according to Example 1, wherein the determining comprises: applying a decoupling model (700) to the at least two image representations (720, 730).

Example 3: Method (2800) according to the preceding example, wherein the decoupling model (700) comprises at least one element from the following group: an empirical model and a transformation model (1500, 2300, 2400, 2500).

Example 4: Method (2800) according to the preceding example, furthermore comprising the step of: adapting the empirical model to the sample (300, 890, 1000).

Example 5: Method (2800) according to the preceding example, furthermore comprising: determining the parameters of the empirical model.

Example 6: Method (2800) according to the preceding example, wherein determining the parameters of the empirical model comprises at least one element from the following group: recording at least two image representations (720, 730) of at least one calibrated test structure at at least partly different solid angles, simulating at least two image representations (720, 730) of the at least one calibrated test structure at at least partly different solid angles, and recording at least two image representations (720, 730) of the at least one calibrated test structure at at least partly different solid angles, wherein at least one detector (870, 2719) has an activated screening grid.

Example 7: Method (2800) according to example 3, wherein the transformation model (1500, 2300, 2400, 2500) comprises at least one transformation model having at least two transformation blocks, each comprising at least one generically learnable function, preferably a machine learning model and/or a generative model (1500, 2300, 2400, 2500).

Example 8: Method (2800) according to example 3 or 7, wherein the transformation model (1500, 2300, 2400, 2500) comprises a machine learning model (2300, 2400, 2500), in particular a deep learning model (1500).

Example 9: Method (2800) according to example 7 or 8, wherein the machine learning model (2300, 2400, 2500) comprises at least one additional parameter (2350) which is provided to the machine learning model (2300, 2400, 2500) at the input (1540, 2310) thereof.

Example 10: Method (2800) according to the preceding example, wherein the at least one additional parameter (2350) comprises a system parameter of a repair device (2700).

Example 11: Method (2800) according to any of Examples 7-10, wherein the machine learning model (2300, 2400, 2500) comprises a hyperparameter (2360) characterizing the sample (300, 890, 1000).

Example 12: Method (2800) according to any of Examples 3 or 7-11, furthermore comprising the step of: training the transformation model (1500, 2300, 2400, 2500) with a training data set.

Example 13: Method (2800) according to the preceding example, wherein the training data set for the transformation model (1500, 2300, 2400, 2500) comprises at least one element from the following group: a multiplicity of tuples of at least two recorded image representations (720, 730) of at least one sample (300, 890, 1000) used for training, a multiplicity of tuples of at least two recorded image representations (720, 730) of at least one test structure used for training, a multiplicity of tuples of at least two simulated image representations (720, 730) of at least one sample (300, 890, 1000) used for training, a multiplicity of tuples of at least two recorded image representations (720, 730) of at least one test structure used for training, wherein the tuples each comprise at least two image representations (720, 730) which were recorded or simulated at at least partly different solid angles relative to the at least one sample (300, 890, 1000) and/or test structure used for training.

Example 14: Method (2800) according to Example 12 or 13, furthermore comprising the following step: recording the training data set for the transformation model (1500, 2300, 2400, 2500).

Example 15: Method (2800) according to any of the preceding examples, wherein determining the topography contrast (585) and/or the material contrast (550, 560) comprises: determining an image representation (510) which comprises substantially no topography contrast portion.

Example 16: Computer program comprising instructions for carrying out the method steps of any of Examples 1 to 15 when the computer program is executed.

Example 17: Device (800, 2700) for determining a topography contrast (585) and/or a material contrast (550, 560) of a sample (300, 890, 1000), comprising:
a. means for providing (850, 870, 2717, 2719) at least two image representations (720, 730) of the sample (300, 890, 1000) recorded at least partly at different solid angles relative to the sample (300, 890, 1000); and
b. means for determining (2780) the topography contrast (585) and/or the material contrast (550, 560) of the sample (300, 890, 1000) at least partly on the basis of the at least two image representations (720, 730) of the sample (300, 890, 1000).

Example 18: Device (800, 2700) according to Example 17, wherein the means for determining (2780) is configured for applying a decoupling model (700) to the at least two image representations (720, 730) for determining the topography contrast (585) and/or the material contrast (550, 560) of the sample (300, 890, 1000).

Example 19: Device (800, 2700) according to Example 17 or 18, wherein the device (800, 2700) comprises at least one first detector (850, 2717) and at least one second detector (870, 2719) for providing the at least two image representations (720, 730) of the sample (300, 890, 1000), wherein the at least one first detector (850, 2717) and the at least one second detector (870, 2719) preferably each detect secondary electrons (SE) and backscattered electrons (BSE) and wherein an SE/BSE ratio of the at least one first detector (850, 2717) and the SE/BSE ratio of the at least one second detector (870, 2719) are preferably different from one another.

Example 20: Device (800, 2700) according to the preceding example, wherein the first detector (850, 2717) is arranged in an electron-optical column of the device (800, 2700), and/or wherein the second detector (870, 2719) is arranged in the electron-optical column of the device (800, 2700).

A number of embodiments of the invention have been described. Nevertheless, it will be understood that various modifications may be made without departing from the spirit and scope of the invention. Accordingly, other embodiments are within the scope of the following claims.

What is claimed is:

1. A method for determining a topography contrast and/or a material contrast of a sample, comprising:
a. providing at least two image representations of the sample recorded at least partly at different solid angles relative to the sample; and
b. determining the topography contrast and/or the material contrast of the sample at least partly on the basis of the at least two image representations of the sample.

2. The method according to claim 1, wherein the determining comprises: applying a decoupling model to the at least two image representations.

3. The method according to claim 2, wherein the decoupling model comprises at least one element from the following group: an empirical model and a transformation model.

4. The method according to claim 3, furthermore comprising the step of: adapting the empirical model to the sample.

5. The method according to claim 4, furthermore comprising: determining the parameters of the empirical model.

6. The method according to claim 5, wherein determining the parameters of the empirical model comprises at least one element from the following group: recording at least two image representations of at least one calibrated test structure at at least partly different solid angles, simulating at least two image representations of the at least one calibrated test structure at at least partly different solid angles, and recording at least two image representations of the at least one calibrated test structure at at least partly different solid angles, wherein at least one detector has an activated screening grid.

7. The method according to claim 3, wherein the transformation model comprises at least one transformation model having at least two transformation blocks, each comprising at least one generically learnable function.

8. The method according to claim 3, wherein the transformation model comprises a machine learning model.

9. The method according to claim 8, wherein the machine learning model comprises at least one additional parameter which is provided to the machine learning model at the input thereof.

10. The method according to claim 9, wherein the at least one additional parameter comprises a system parameter of a repair device.

11. The method according to claim 7, wherein the machine learning model comprises a hyperparameter characterizing the sample.

12. The method according to claim 3, furthermore comprising the step of: training the transformation model with a training data set.

13. The method according to claim 12, wherein the training data set for the transformation model comprises at least one element from the following group: a multiplicity of tuples of at least two recorded image representations of at least one sample used for training, a multiplicity of tuples of at least two recorded image representations of at least one test structure used for training, a multiplicity of tuples of at least two simulated image representations of at least one sample used for training, a multiplicity of tuples of at least two recorded image representations of at least one test structure used for training, wherein the tuples each comprise at least two image representations which were recorded or simulated at at least partly different solid angles relative to the at least one sample and/or test structure used for training.

14. The method according to claim 12, furthermore comprising the following step: recording the training data set for the transformation model.

15. The method according to claim 1, wherein determining the topography contrast and/or the material contrast comprises: determining an image representation which comprises substantially no topography contrast portion.

16. A computer program comprising instructions for carrying out the method steps of claim 1 when the computer program is executed.

17. A device for determining a topography contrast and/or a material contrast of a sample, comprising:
a. means for providing at least two image representations of the sample recorded at least partly at different solid angles relative to the sample; and
b. means for determining the topography contrast and/or the material contrast of the sample at least partly on the basis of the at least two image representations of the sample.

18. The device according to claim 17, wherein the means for determining is configured for applying a decoupling model to the at least two image representations for determining the topography contrast and/or the material contrast of the sample.

19. The device according to claim 17, wherein the device comprises at least one first detector and at least one second detector for providing the at least two image representations of the sample.

20. The device according to claim 19, wherein the first detector is arranged in an electron-optical column of the device, and/or wherein the second detector is arranged in the electron-optical column of the device.
